(19) United States
(12) Patent Application Publication
(10) Pub. No.: US 2024/0071871 A1
(43) Pub. Date: Feb. 29, 2024

(54) 3D HIGH DENSITY DEVICES INTEGRATED WITH SOURCE AND DRAIN RAILS

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/900,498

(22) Filed: Aug. 31, 2022

(51) Int. Cl. H01L 23/48; H01L 27/088; H01L 29/08; H01L 29/10; H01L 29/66; H01L 29/78

(52) U.S. Cl. CPC H01L 23/481; H01L 27/0886; H01L 29/0847; H01L 29/1033; H01L 29/66795; H01L 29/7851

(57) ABSTRACT

Systems and methods for manufacturing three-dimensional (3D) high density devices that are integrated with source and drain rails. The system can include a semiconductor device. The semiconductor device can include a conductor rail disposed below one or more transistors. The conductor rail can further include a first portion and a second portion arranged in parallel with each other. The semiconductor device can include a lower source/drain region disposed above the conductor rail. The semiconductor device can include a channel region disposed above the lower source/drain region. The semiconductor device can include an upper source/drain region disposed above the channel region. The lower source/drain region, the channel region, and the upper source/drain region each can include a semiconductor material. The semiconductor device can include a gate structure disposed around at least the channel region.

### FIELD OF THE DISCLOSURE

This disclosure relates to non-planar, or three-dimensional (3D), structures and transistors. Channel regions of the disclosed transistor structures may be oriented to conduct current in a direction generally perpendicular to a major surface of the system or chip upon which, or within which, these structures are provided.

### BACKGROUND

Fabrication of semiconductor devices relies on execution of various fabrication processes that are performed repeatedly in order to form desired semiconductor features on a substrate. In the recent years, scaling down semiconductor devices became more challenging as sizes of features reached single digit nanometer range.

In the manufacture of semiconductor devices (especially, on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes.

### SUMMARY

In order to continue scaling down semiconductor devices, device structures can be designed to extend in their vertical direction, such as upwards from the substrate on which they are fabricated. The present disclosure provides three-dimensional (3D) semiconductor circuits in which transistor structures can be designed to extend in vertical direction, as well as be stacked on top of each other, thereby allowing for greater number of devices to be fabricated within a substrate surface area. For example, each transistor structure, as disclosed herein, includes a vertically oriented nanosheet functions as its (conduction) channel. Such a nanosheet can be formed based on a stack formed over the substrate. By exposing at least a top surface and bottom surface of the nanosheet, source and drain regions can be formed from the nanosheet by doping. In this way, the conductive type of each transistor structure can be customized, and its source and drain regions can be self-aligned with its channel (e.g., nanosheet). Further, the stack can include a multiple number of such nanosheets, which allows a number of transistor structures to be stacked on top of one another, and the transistor structures can have either the same conductive type or different conductive types.

Thus, three-dimensional (3D) integration (e.g. the vertical stacking of multiple devices) aims to overcome scaling limitations experienced in planar devices by increasing transistor density in volume rather than area. Three-dimensional integration as applied to random logic designs is more difficult than alternative approaches. Three-dimensional integration for logic chips (e.g., CPU (central processing unit), GPU (graphics processing unit), FPGA (field programmable gate array, SoC (System on a Chip), etc.) may be desired.

The techniques described herein include methods and devices for 3D fabrication of the semiconductor devices. Specifically, techniques may include self-aligned metal routing for vertical channel transistors achieved with 360 degree symmetry for 3D vertical transistors. Compact circuit layout may be obtained with such techniques. Techniques herein can be used for any geometry device (i.e., circular, rectangular, and/or ellipse shape).

Typically, the high volume manufacturing of horizontal two-dimensional (2D) transistors suffers from gate pitch scaling limits, less optimal device performance, and issues with 3D transistor stacking. To solve this problem, the present disclosure provides high-density three-dimensional transport v-shaped notch channel field effect transistor (VFET) nanosheet source/drain rails. The VFET nanosheets overcome the gate-pitch scaling limits. The VFET nanosheets also offer better electrostatics and dynamic performance at contacted gate pitch (CGP) below 45 nanometers with improved ring oscillator (R/O) performance.

The present disclosure provides a source rail that is self-aligned beneath the three-dimensional transistor with a single crystal semiconductor source. To augment the three-dimensional stack height, the present disclosure uses wafer bonding. The transport nanosheets display better slow-slow process corners, drain-induced barrier lowering, and enhanced device operation in comparison with, for example, a fin-shaped field effect transistor (FinFET). To achieve these properties, the present disclosure includes aggressively scaled gate pitches. 3D transport nanosheets can avoid or substantially reduce lateral field effect transistor scaling limits to deliver and enhance an operating voltage range. 3D transport nanosheets can also provide greater drive strength and flexibility compared to FinFETs and nanowires. Transport nanosheets have an intrinsic benefit of approximately 50 percent capacitance reduction over a scaled later field effect transistor. The present disclosure provides vertical transport nanosheets to scale beyond the limits of lateral transport field effect transistor (FET) nanosheet architectures. The vertical device architecture provides an increase of approximately 50 percent in ring oscillator (R/O) performance. The vertical device architecture provides greatly reduced circuit capacitance. Additionally, the present disclosure provides an efficient process flow with few masking steps.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In one aspect of the present disclosure, a semiconductor device includes a conductor rail disposed below one or more transistors wherein the conductor rail includes a first portion and a second portion arranged in parallel with each other. The semiconductor device includes a lower source/drain region disposed above the conductor rail. The semiconductor device includes a channel region disposed above the lower source/drain region. The semiconductor device includes an upper source/drain region disposed above the channel region. In some embodiments, the lower source/drain region, the channel region, and the upper source/drain region each include a semiconductor material. The semiconductor device includes a gate structure disposed around at least the channel region.

In some embodiments, the lower source/drain region is in physical and electrical contact with the first and second portions of the conductor rail. In some embodiments, the semiconductor device includes a dielectric spacer disposed between the gate structure and the conductor rail, and further disposed around the lower source/drain region. In some embodiments, the semiconductor device includes a first via in physical and electrical contact with at least one of the first or second portion of the conductor rail. In some embodiments, the semiconductor device includes a second via in physical and electrical contact with the gate structure. In some embodiments, the semiconductor device includes a third via in physical and electrical contact with the upper source/drain region.

In some embodiments, the semiconductor device includes a second lower source/drain region also disposed above the conductor rail. In some embodiments, the semiconductor device includes a second channel region disposed above the second lower source/drain region. In some embodiments, the semiconductor device includes a second upper source/drain region disposed above the second channel region. In some embodiments, the second lower source/drain region, the second channel region, and the second upper source/drain region each include the semiconductor material. In some embodiments, the semiconductor device includes a second gate structure disposed around at least the second channel region. In some embodiments, the lower source/drain region, the channel region, the upper source/drain region, and the gate structure collectively function a first transistor, and the second lower source/drain region, the second channel region, the second upper source/drain region, and the second gate structure collectively function a second transistor.

In some embodiments, the first transistor and second transistor share the conductor rail as their common source rail. In some embodiments, the semiconductor device includes a plurality of drain rails that are arranged in parallel with one another and in electrical contact with the upper source/drain region and the second upper source/drain region, respectively. In some embodiments, the common source rail extends in a first lateral direction, with the drain rails extending in a second lateral direction different from the first lateral direction.

In some embodiments, the semiconductor device includes a second conductor rail including a first portion and second portion arranged in parallel with each other, the second conductor rail disposed above the upper source/drain region. In some embodiments, the semiconductor device includes a second lower source/drain region disposed above the second conductor rail. In some embodiments, the semiconductor device includes a second channel region disposed above the second lower source/drain region. In some embodiments, the semiconductor device includes a second upper source/drain region disposed above the second channel region. In some embodiments, the second lower source/drain region, the second channel region, and the second upper source/drain region each include the semiconductor material. In some embodiments, the semiconductor device includes a second gate structure disposed around at least the channel region. In some embodiments, the lower and upper source/drain regions have a first conductive type, and the second lower and upper source/drain regions have a second conductive type opposite to the first conductive type.

In one aspect of the present disclosure, a semiconductor device includes a conductor rail extending along a first lateral direction. The semiconductor device includes a plurality of transistors disposed above the conductor rail and spaced from one another along the first lateral direction. In some embodiments, the plurality of transistors includes a lower source/drain region disposed above the conductor rail. In some embodiments, the plurality of transistors includes a channel region disposed above the lower source/drain region. In some embodiments, the plurality of transistors includes an upper source/drain region disposed above the channel region. In some embodiments, the lower source/drain region, the channel region, and the upper source/drain region each include a semiconductor material. The semiconductor device includes a gate structure disposed around at least one channel region.

In some embodiments, the semiconductor device includes a second conductor rail in parallel with the conductor rail. In some embodiments, the semiconductor device includes a plurality of second transistors disposed above the second conductor rail and spaced from one another along the first lateral direction. In some embodiments, each of the plurality of second transistors includes a second lower source/drain region disposed above the second conductor rail. In some embodiments, each of the plurality of second transistors includes a second channel region disposed above the second lower source/drain region. In some embodiments, each of the plurality of second transistors includes a second upper source/drain region disposed above the second channel region, wherein the second lower source/drain region, the second channel region, and the second upper source/drain region each include the semiconductor material. In some embodiments, each of the plurality of second transistors includes a second gate structure disposed around at least the second channel region.

In some embodiments, the lower source/drain region, the upper source/drain region, the second lower source/drain region, and the second upper source/drain region all have a same conductive type. In some embodiments, the semiconductor device includes a second conductor rail disposed above the upper source/drain region of each of the transistors. In some embodiments, the semiconductor device includes a second lower source/drain region disposed above the second conductor rail. In some embodiments, the semiconductor device includes a second channel region disposed above the second lower source/drain region. In some embodiments, the semiconductor device includes a second upper source/drain region disposed above the second channel region, wherein the second lower source/drain region, the second channel region, and the second upper source/drain region each include the semiconductor material. In some embodiments, the semiconductor device includes a second gate structure disposed around at least the second channel region.

In some embodiments, the lower and upper source/drain regions have a first conductive type, and the second lower and upper source/drain regions have a second conductive type opposite to the first conductive type. In some embodiments, the plurality of transistors share the conductor rail as their common source rail. In some embodiments, the semiconductor device includes a plurality of drain rails that are arranged in parallel with one another and in electrical contact with the upper source/drain regions of the plurality of transistors, respectively. In some embodiments, the drain rails extend in a second lateral direction different from the first lateral direction.

In one aspect of the present disclosure, a method for fabricating semiconductor devices includes forming, over a substrate, a semiconductor feature (e.g., formed in a fin-like structure) extending along a lateral direction. A method for fabricating semiconductor devices includes forming a conductor rail below the semiconductor feature and also extending along the lateral direction. A method for fabricating semiconductor devices includes separating the semiconductor feature into a plurality of channel regions spaced from one another along the lateral direction. A method for fabricating semiconductor devices includes forming a plurality of gate structures, each of the plurality of gate structures surrounding a corresponding one of the plurality of channel regions.

In some embodiments, the method for fabricating semiconductor devices includes prior to forming the gate structures, forming a plurality of dielectric spacers, each of the plurality of dielectric spacers surrounding a corresponding one of the plurality of channel regions. In some embodiments, the method for fabricating semiconductor devices includes recessing the plurality of dielectric spacers such that each of the plurality of recessed dielectric spacers surrounding a lower portion of the corresponding channel region that has been converted into a source/drain region.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of an example method for making a semiconductor device, in accordance with some embodiments.

FIGS. 2 to 19 illustrate respective cross-sectional or top views of a semiconductor device during various fabrication stages of the method of FIG. 1, in accordance with some embodiments.

FIG. 20 illustrates a flow chart of another example method for making a semiconductor device, in accordance with some embodiments.

FIGS. 21 to 23 illustrate respective cross-sectional or top views of a semiconductor device during various fabrication stages of the method of FIG. 20, in accordance with some embodiments.

FIG. 24 illustrates a flow chart of another example method for making a semiconductor device, in accordance with some embodiments.

FIGS. 25 to 28 illustrate respective cross-sectional or top views of a semiconductor device during various fabrication stages of the method of FIG. 24, in accordance with some embodiments.

FIG. 29 illustrates a cross-sectional view of a semiconductor device formed according to another example method, in accordance with some embodiments.

FIG. 30 illustrates a flow chart of another example method for making a semiconductor device, in accordance with some embodiments.

FIGS. 31 to 41 illustrate respective cross-sectional or top views of a semiconductor device during various fabrication stages of the method of FIG. 30, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a circular configuration, other shapes are also contemplated, and indeed the techniques described herein may be implemented in any shape or geometry.

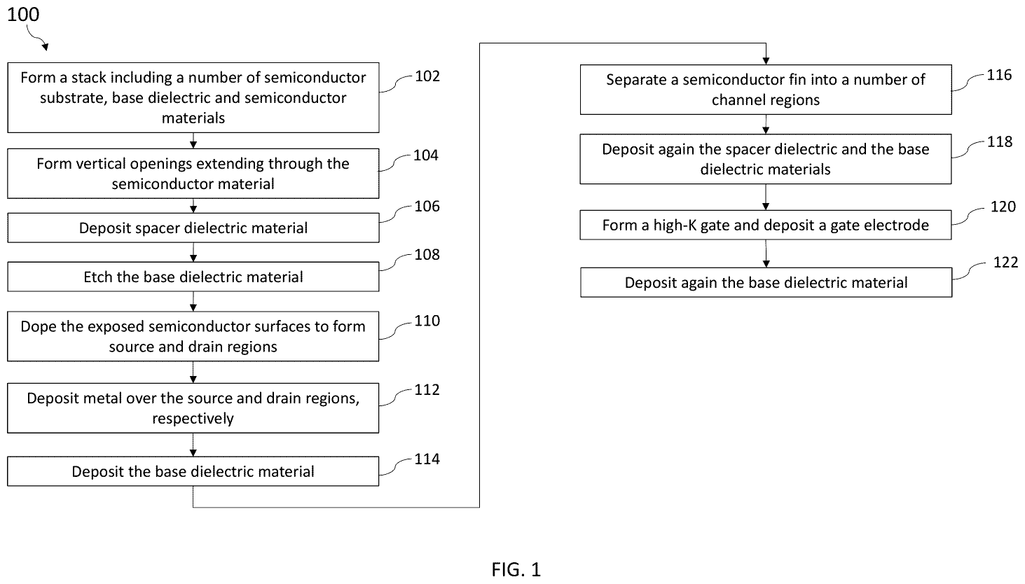

FIG. 1 illustrates a flowchart of an example method 100 for forming a semiconductor device (e.g., including one or more transistor structures) based on a vertical nanosheet. For example, each of the transistor structures may be a vertical transistor having its channel region (implemented as a nanosheet) extending along a vertical direction, its source/drain regions formed by plasma doping from (and self-aligned with) the channel region along that vertical direction, and its gate surrounding the channel region. Further, through performing at least some of operations of the method 100, gate electrodes can be disposed on one or more source/drain regions of the transistor. It is noted that the method 100 is merely an example, and is not intended to limit the present disclosure. Accordingly, it is understood that additional operations may be provided before, during, and after the method 100 of FIG. 1, and that some other operations may only be briefly described herein.

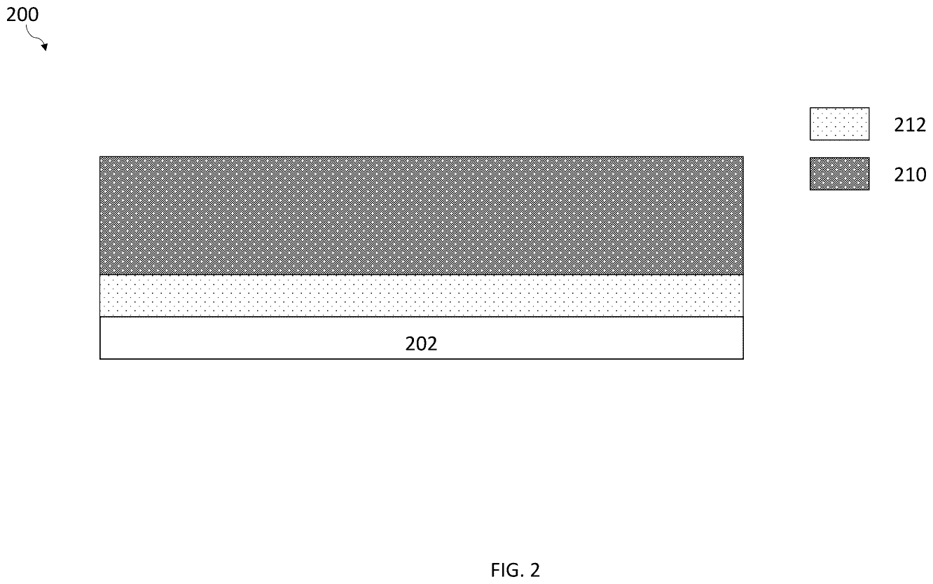

In various embodiments, operations of the method 100 may be associated with top views or cross-sectional views of an example semiconductor device 200 at various fabrication stages as shown in FIGS. 2 to 19, which will be discussed in further detail below. It should be understood that the semiconductor device 200, shown in FIGS. 2 to 19, may include a number of other devices such as inductors, fuses, capacitors, coils, etc., while remaining within the scope of the present disclosure.

FIG. 1 illustrates a flowchart of an example method 100 for forming a 3D high density transport device, for example, an NMOS (N-type Metal Oxide Semiconductor) device field effect transistor wherein the source and the drain regions are formed of n-type semiconductors) integrated with metal source rail wherein, for example, a selective metal rail formation or deposition can be used. Although the semiconductor devices 200 fabricated using NMOS device is described according to the method 100, it should be understood that that any type of MOSFET device, for example, the device having a conductive type opposite to the NMOS device, such as a PMOS (P-type Metal Oxide Semiconductor) field effect transistor with its source and the drain regions formed of p-type semiconductors, can be used to form the 3D high density transport device integrated with the metal source rail.

In brief overview, the method 100 starts with operation 102 of forming a stack of base dielectric and semiconductor materials over a substrate. The method 100 continues to operation 104 of patterning the semiconductor material and forming a number of vertical openings extending through the semiconductor material. The method 100 proceeds to operation 106 of depositing a dielectric spacer material in the vertical openings to surround the remaining semiconductor material. In some embodiments, the remaining semiconductor material may be configured as a number of semiconductor features (e.g., formed in a fin-like structure) protruding from the base dielectric material. The method 100 proceeds to operation 108 of forming a space underneath each of the semiconductor features by etching the base dielectric material. The method 100 proceeds to operation 110 of forming a source region and drain region at top and bottom surfaces of each of the semiconductor features, respectively by, for example, plasma doping. The method 100 proceeds to operation 112 of deposing a metal material over the source and drain regions. The method 100 proceeds to operation 114 of depositing the base dielectric material. The method 100 proceeds to operation 116 of separating the semiconductor feature into a number of channel regions. The method 100 proceeds to operation 118 of depositing again the spacer dielectric material to surround each of the channel regions and then depositing the base dielectric material to surround the spacer dielectric material. The method 100 proceeds to operation 120 of patterning the spacer and base dielectric materials and forming a gate structure around each of the channel regions.

Corresponding to operation 102 of FIG. 1, FIG. 2 is a cross-sectional view of the semiconductor device 200 in which, over a substrate 202, a stack including a semiconductor material 210 and a base dielectric material 212 are formed, in accordance with various embodiments.

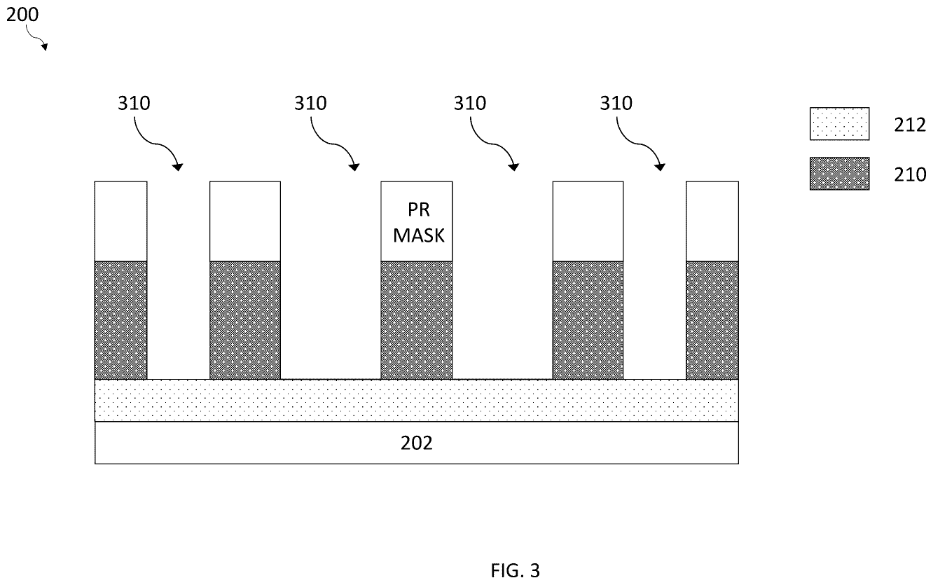

As shown, over the substrate 202, the base dielectric material 212 is firstly formed, followed by a semiconductor material 210. Over a topmost one of the materials of the stack (e.g., the semiconductor material 210 in the example of FIG. 2), a hardmask layer can be formed to facilitate the following patterning process (e.g., FIG. 3).

The substrate 202 includes a semiconductor material substrate, for example, silicon. Alternatively, the substrate 202 may include other elementary semiconductor material such as, for example, germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. In one embodiment, the substrate 202 includes an epitaxial layer. For example, the substrate 202 may have an epitaxial layer overlying a bulk semiconductor. Furthermore, the substrate 202 may include a semiconductor-on-insulator (SOI) structure. For example, the substrate 202 may include a buried oxide (BOX) layer formed by a process such as separation by implanted oxygen (SIMOX) or other suitable technique, such as wafer bonding and grinding.

The base dielectric material 212 may include at least one insulation material, which can electrically isolate neighboring active structures (e.g., metal electrodes which will be formed below) from each other. The insulation material may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed.

Corresponding to operation 104 of FIG. 1, FIG. 3 is a cross-sectional view of the semiconductor device 200 in which a number of first vertical openings 310 are formed to extend through the semiconductor material 210, in accordance with various embodiments. Thus, the width of each individual semiconductor feature (e.g., formed in a fin-like structure) 412 is defined.

One or more masks can be formed above the mask material using at least one suitable masking technique. Once the masks are formed, one or more etch techniques may be performed to remove the portion of the underlying materials aligned with the opening in the mask (e.g., portions of underlying materials not covered with the mask). Any type of suitable etching techniques may be used, including but not limited to dry etching, wet etching, or plasma etching techniques. The mask may be removed once the etching process to remove a portion of the materials is completed. Hereinafter, to remove one or more described materials, one or more masks and etching techniques can be used as discussed above. The etching process can remove materials in any geometry, such as vertically or diagonally. The dimension (e.g., width or diameter) of the masks can correspond to the dimension of the opening (e.g., removed portions of the materials) or the dimension of the underlying materials of the masks.

Following the formation of the hardmask layer (not shown), a patternable layer (e.g., a photoresist mask) with patterns is formed over the hardmask layer. Next, at least one dry etching or a wet etching process including, e.g., dilute hydrofluoric (DHF) acid, may be performed to etch the semiconductor material 210 until the base dielectric 212 is exposed so as to form the first vertical openings 310. The remaining semiconductor material 210 between the first vertical openings 310 can define a number of lateral semiconductor fins 412. Thus, the first vertical openings 310 can define respective widths of a number of semiconductor fins 412 on the substrate 202, the width defined by the remaining semiconductor material 210 in each of the semiconductor fin 412. Further, the first vertical openings 310 can be formed with any of various cross-section profiles. For example, each of the first vertical openings 310 can have a square, triangular, circular, elliptical, or any other cross-section, which will be shown below.

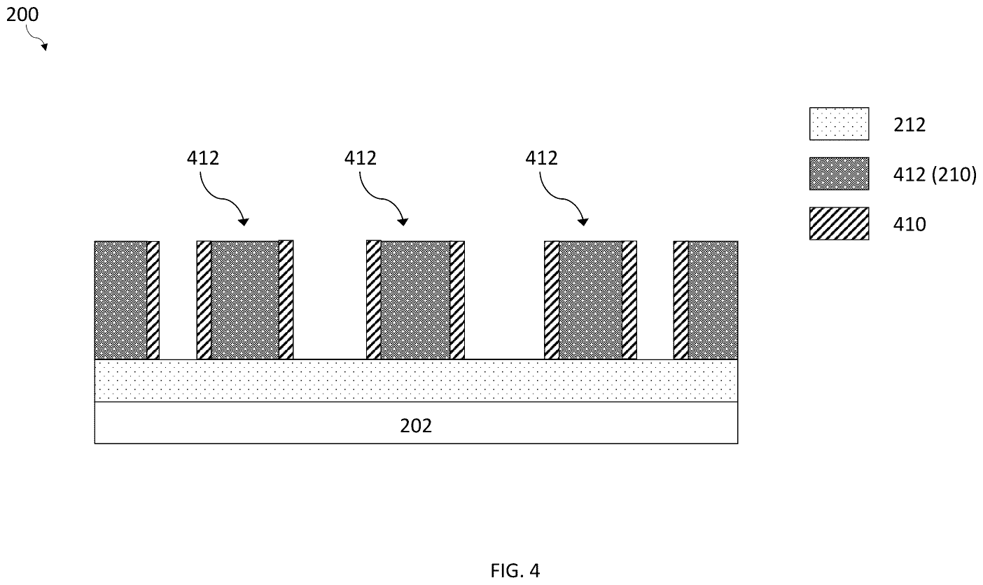

Corresponding to operation 106 of FIG. 1, FIG. 4 is a cross-sectional view of the semiconductor device 200 in which a spacer dielectric material 410 is formed around each of semiconductor fins 412, in accordance with various embodiments.

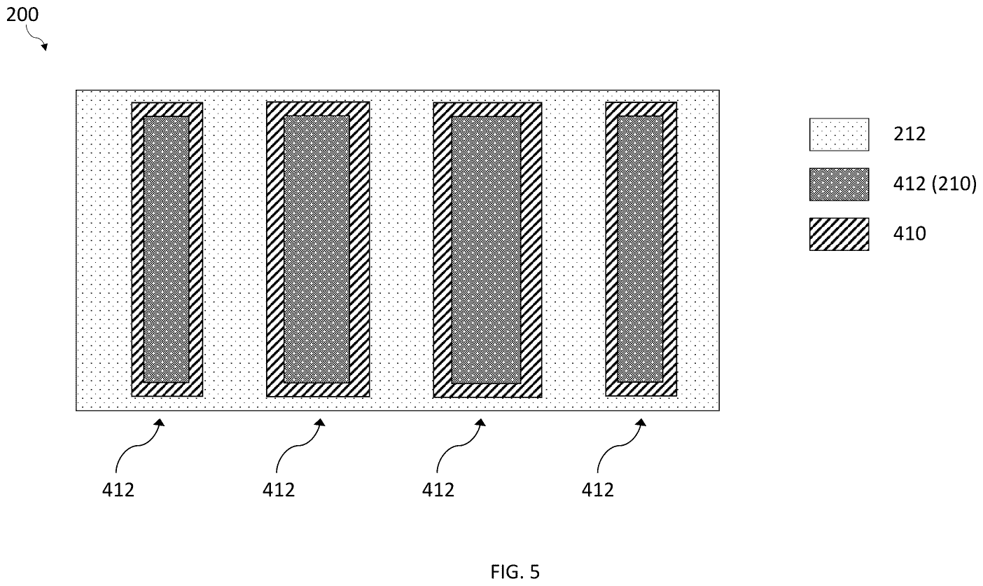

The spacer dielectric material 410 is configured to electrically isolate the corresponding semiconductor fins 412. To illustrate the exposed portion of each of the semiconductor fins 412, a top view of the semiconductor device 200 is shown in FIG. 5. In some embodiments, the spacer dielectric material 410 may be formed by performing at least some of the following processes: filling the first vertical openings 310 with the spacer dielectric material 410 and partially removing the spacer dielectric material 410 to form such structure of the spacer dielectric material 410 so as to wrap around the semiconductor fins 412 with the spacer dielectric material 410.

For example, a patternable layer (e.g., a photoresist mask) can be formed over the workpiece, e.g., with the hardmask layer disposed above the spacer dielectric material 410 and the semiconductor material 210 disposed therein. Further, the patternable layer can have a pattern (e.g., one or more openings) overlaying a portion of each of the semiconductor fins 412 and portions of the spacer dielectric material 410 wrapping the semiconductor fins 412. By performing at least one etching process with the patternable layer as a mask, one or more openings can be formed, which can expose a portion of a sidewall of the spacer dielectric material 410 that wraps around each of the semiconductor fins 412. Following the deposition of the spacer dielectric material 410, an etching process may be performed to remove excessive spacer dielectric material 410.

The spacer dielectric material may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used for forming the spacer dielectric material 410.

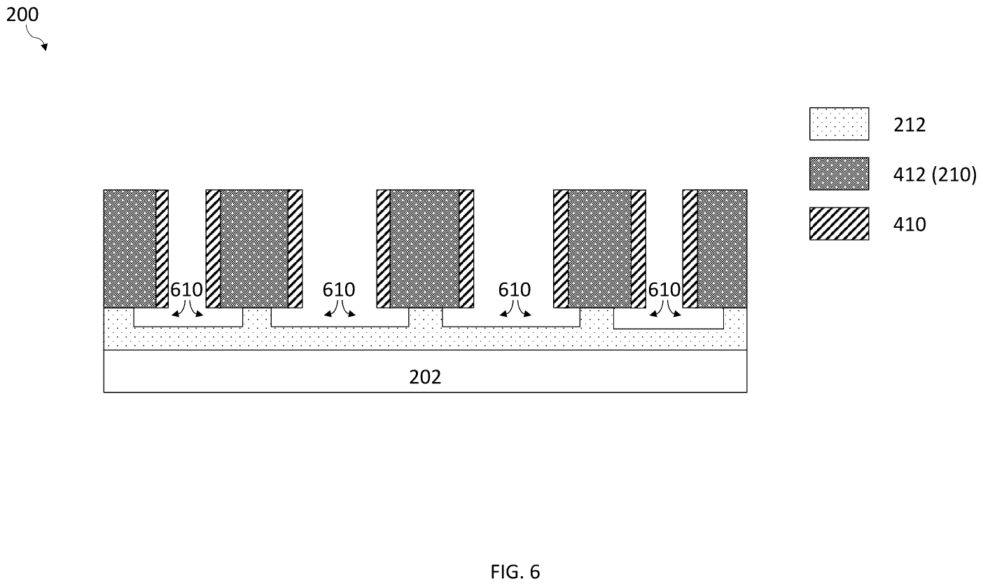

Corresponding to operation 108 of FIG. 1, FIG. 6 is a cross-sectional view of the semiconductor device 200 in which the base dielectric material 212 is patterned to form cavities 610, thereby exposing a base portion of each of the semiconductor fins 412, in accordance with various embodiments.

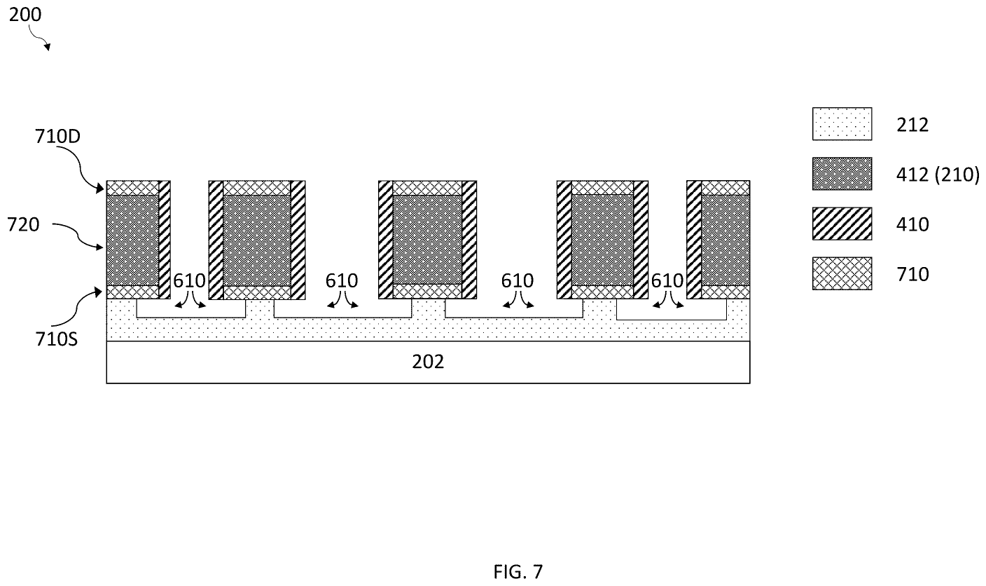

In some embodiments, the cavities 610 may be formed by performing at least some of the following processes to provide an access for doping (by, e.g., plasma doping with ion implants) of the base and the topmost surfaces of the semiconductor fins 412 (FIG. 4) so as to form source and drain regions (as illustrated in FIG. 7). For example, a patternable layer (e.g., a photoresist mask) can be formed over the workpiece, e.g., with the hardmask layer and the spacer dielectric material 410 and the semiconductor material 210 disposed therebelow. Further, the patternable layer can have a pattern (e.g., one or more openings) overlaying a portion of each of the semiconductor fins 412 and portions of the spacer dielectric material 410 wrapping the semiconductor fins 412. By performing at least one etching process with the patternable layer as a mask, one or more openings in the base dielectric material 212 underneath the base of the semiconductor fins 412 can be formed. These openings or cavities 610 can expose a portion of the base of each of the semiconductor fins 412.

For example, using the mask and etching process, portions of the base dielectric materials 212 can be removed or otherwise patterned. In this case, the openings 610 formed via the etching process can be vertically extended to at least the base dielectric material 212. A portion of the bottom spacer dielectric material 410 and the semiconductor material 210 (e.g., a portion of a base S/D region that is described below in further detail) may not be removed (due to, for example, etching selectivities of the spacer dielectric material 410 and the semiconductor material 210 being different from etching selectivities of the base dielectric material 212). Therefore, this portion of the bottom spacer dielectric material 410 and the semiconductor material 210 remains laterally extended beyond the dimension of the mask.

The base dielectric material 212 may have different etching selectivities at its different portions. For example, the first portion of the base dielectric material 212 may have a different etching selectivity from the second portion of the base dielectric material 212, the second portion of the base dielectric material 212 disposed at least partially below the semiconductor material 210. As such, while the first portion of the base dielectric material 212 is being etched, the second portion of the base dielectric material 212 may remain substantially intact. Alternatively or optionally the base dielectric material 212 may be formed of two or more base dielectric materials: a first base dielectric material and a second base dielectric material (not shown). The first base dielectric material may have different etching selectivity from the second base dielectric material and the second base dielectric material may be disposed at least partially below the semiconductor material 210. As such, while the first base dielectric material is being etched, the second base dielectric material may remain substantially intact.

In various embodiments, a first portion of the base dielectric material 212 can be removed according to the dimension of the mask, thereby having a sidewall that aligns such that the sidewall of the cavity 610 is disposed below the semiconductor material 210 and at least one topmost side of the cavity is formed at least partially by the semiconductor material 210. A second portion of the base dielectric material 212 may not be removed due to, for example, etching properties of the second portion of the base dielectric material 212 being different from the etching selectivity of the first portion of the base dielectric material 212. Hence, the second portion of the base dielectric material 212 can be disposed besides the first portion and laterally extend beyond the sidewall of the first portion, i.e. beyond the sidewall of the cavity 610. In various implementations, this etching process may not remove materials down to at least one of the semiconductor substrate 202.

Corresponding to operation 110 of FIG. 1, FIG. 7 is a cross-sectional view of the semiconductor device 200 in which a number of self-aligned source/drain regions 710 are formed, in accordance with various embodiments.

After forming the cavities 610, the source/drain regions 710 can be formed by doping (e.g., plasma doping) a portion of the semiconductor material 210 from the exposed surfaces. Specifically, the source/drain regions 710 can be formed along the bottom/lower (or base) and top/upper surfaces of each of the semiconductor material 210. Thus, one or more semiconductor channels or channel regions can be later formed in the corresponding semiconductor fin 412 to electrically couple to the corresponding source and drain regions 710. As such, the semiconductor material 210 in each of the semiconductor fins 412 may be vertically sandwiched by a pair of the source/drain regions 710, one of which may operatively serve as a source region 710S and the other of which may operatively serve as a drain region 710D, as shown in the cross-sectional view of FIG. 7.

(In various embodiments, the source/drain regions 710 may be implanted with dopants to form doped source/drain regions 710 followed by an annealing process. For example, when a resultant transistor is configured in n-type, the doped source/drain regions 710 can include silicon carbide (SiC), silicon phosphorous (SiP), phosphorous-doped silicon carbon (SiCP), or the like. When the resultant transistor is configured in a p-type, the source/drain regions 710 can include SiGe, and a p-type impurity such as boron or indium. In some embodiments, the source/drain regions 710 may be in situ doped during their formation.

For example, a plasma doping of the both ends of the semiconductor material 210 not covered by the spacer dielectric 410 or base dielectric 212 can be performed for each of the transistor structures so as to p-type dope the topmost side of the semiconductor material 210 and the bottommost base area of the semiconductor material 210 that is adjacent to the cavity or opening 610 so as to form the n-type S/D regions 710S and 710D.

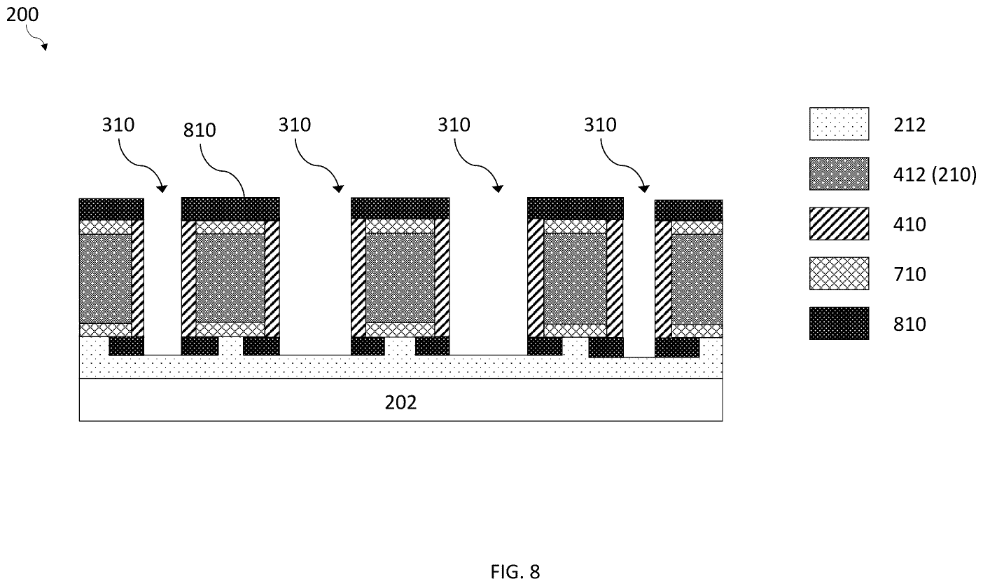

Corresponding to operation 112 of FIG. 1, FIG. 8 is a cross-sectional view of the semiconductor device 200 in which metal deposition is selectively formed at the top and base of the transistor, in accordance with various embodiments.

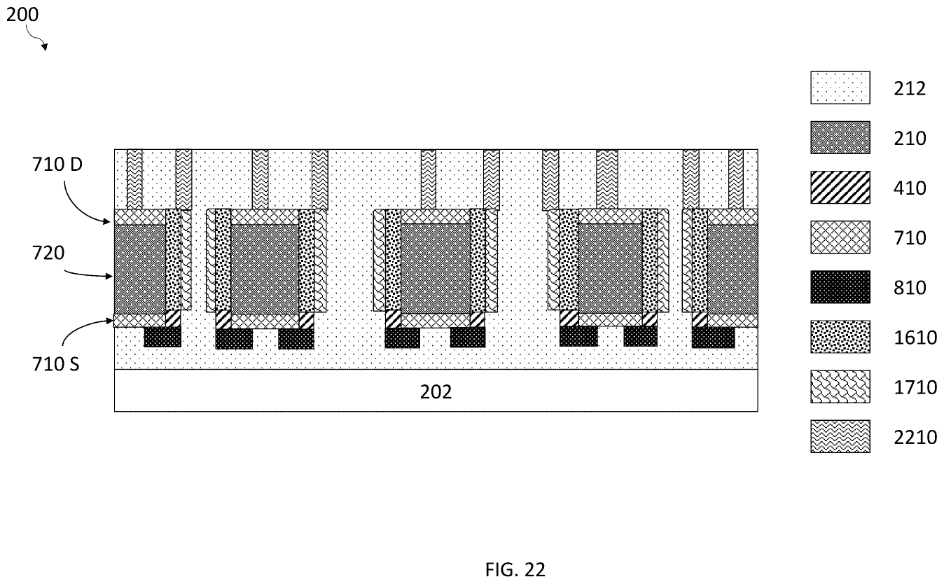

For example, FIG. 8 illustrates a cross-sectional view of the semiconductor device 200 including metal routings. In various implementations, the openings formed via the etching technique can be used to selectively deposit one or more metal structures or materials, for example source/drain metal (S/D metal) 810, such as to route at least one of the S/D regions 710D, 710S S/D region for (e.g., electrical and/or physical) connection above the semiconductor fins 412. The metal routing can be formed with one or more metal structures selectively deposited using at least one suitable deposition technique, for example. The selective deposition of metal and etching are performed such as to vertically align an edge of the spacer dielectric 410 with an edge of the S/D metal 810 disposed within the cavity or opening 610 of each of the corresponding semiconductor fins 412. These metal routings can be used to hookup the semiconductor device to the power source (as illustrated, for example, in FIG. 22).

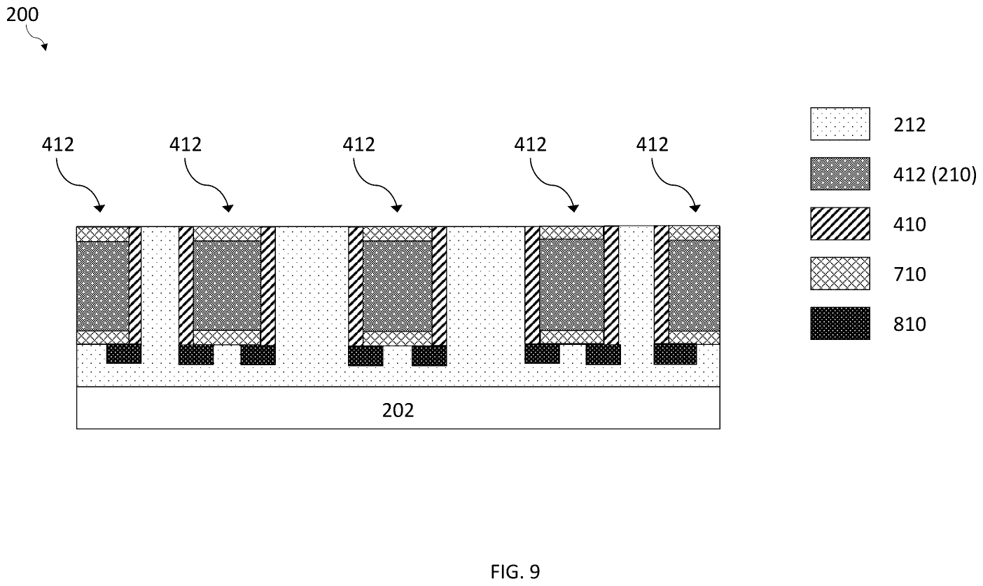

Corresponding to operation 112 of FIG. 1, FIG. 9 is a cross-sectional view of the semiconductor device 200 in which the metal routing 810 (e.g., drain metal) is removed from the top side of the transistor by the techniques described herein, for example, by etching and performing the CMP. The CMP can be performed to clear any surplus material from this deposition.

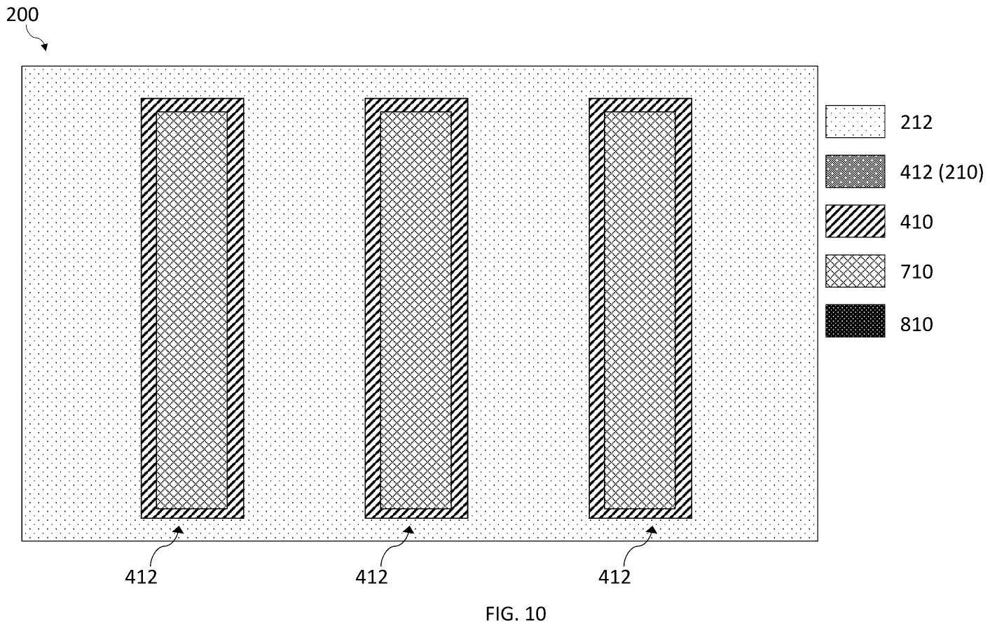

Corresponding to operation 114 of FIG. 1, FIG. 9 is a cross-sectional view of the semiconductor device 200 in which the first vertical spaces 310 are filled with the base dielectric material 212. The base dielectric material 212 is configured to electrically isolate the corresponding semiconductor fins 412. To illustrate the exposed portion of each of the semiconductor fins 412, a top view of the semiconductor device 200 is shown in FIG. 10. In some embodiments, the base dielectric material 212 may be formed by performing at least filling the first vertical openings 310 with the base dielectric material 212. Following the selective deposition of the base dielectric material 212, an etching process may be performed to remove excessive dielectric material.

Corresponding to operation 116 of FIG. 1, FIG. 9 is a cross-sectional view of the semiconductor device 200 in which etching the topmost S/D region 710, spacer dielectric material 410 and the base dielectric material 212 is performed according to the etching techniques described herein. Also, corresponding to operation 116 of FIG. 1, FIG. 10 is a top view of the semiconductor device 200 in which the CMP is performed to clean the top surface after etching.

FIG. 10 illustrates the top view of the semiconductor device 200 showing the semiconductor fins 412 disposed on their respective source metal or rails 810. In FIG. 10 the source metal 810 that is disposed at the base of each of the semiconductor fins 412 is not shown because the source metal 810 is disposed beneath the base S/D region 710 and the spacer dielectric 410.

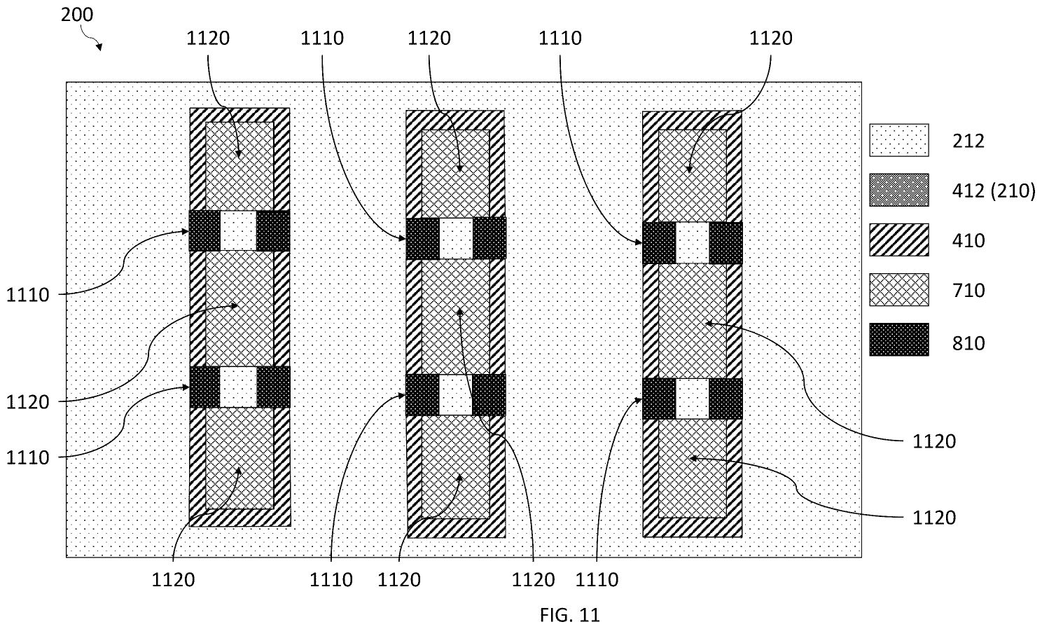

Corresponding to operation 116 of FIG. 1, FIG. 11 is a top view of the semiconductor device 200 in which patterning of the lateral semiconductor fins 412 is performed and a number of second vertical openings 1110 are formed to extend through the lateral semiconductor fins 412, in accordance with various embodiments. Thus, the length of each S/D regions 710D and 710S as well as a channel region 720 of each individual transistor is defined.

Any type of suitable masking techniques may be used to form the second vertical openings 1110. For example, a patternable layer (e.g., a photoresist mask) can be formed over the workpiece, e.g., with the hardmask layer disposed above the base dielectric material 212 and respective vertical portions 1120 of each lateral semiconductor fin 412 that will be divided or spaced apart by the second vertical openings 1110. Further, the patternable layer can have a pattern (e.g., one or more openings) overlaying a vertical portion 1120 of each of the lateral semiconductor fin 412. By performing at least one etching process described herein with the patternable layer as a mask, one or more second vertical openings 1110 can be formed, which can expose at least some of the inner vertical sides of the vertical portions 1120 of each of the lateral semiconductor fin 412. Thus, the length of each individual vertical portion 1120 is defined that further defines the length of each S/D regions 710D and 710S as well as a channel region 720 of each individual transistor.

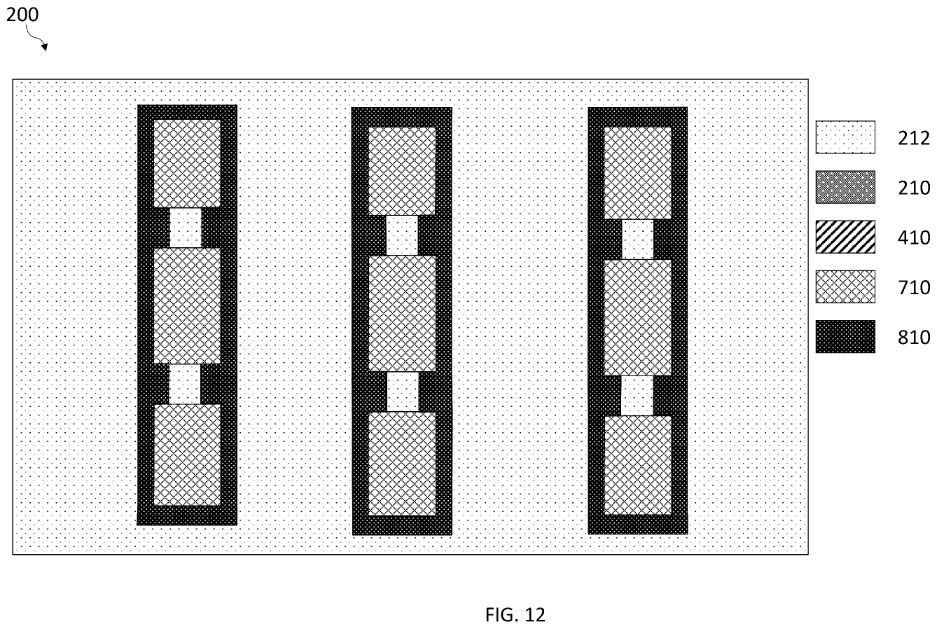

FIG. 12 illustrates the top view of the semiconductor device 200 showing the portions or vertical structures 1120 of the semiconductor fins 412 disposed on their respective source metal or rails 810, wherein the spacer dielectric 410 is removed from the top view for clarity. In FIG. 12 the source metal 810 that is disposed at the base of each of the portions 1120 of the semiconductor fins 412 is partially shown because the spacer dielectric 410 is removed from the top view for clarity. The source metal rail 810 is illustrated as partially disposed beneath the base S/D region 710. Though the source metal rail 810 is illustrated as a common source for several transistors, the source metal rail 810 can be formed as an individual source, e.g., electrically and/or physically coupling the lower S/D region 710S of only one transistor.

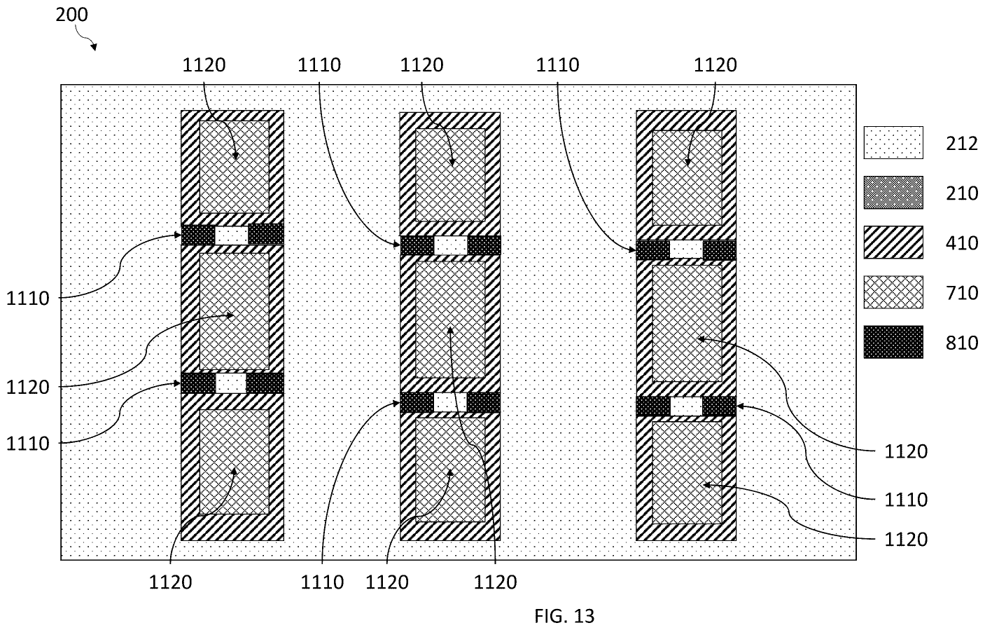

Corresponding to operation 118 of FIG. 1, FIG. 13 is a cross-sectional view of the semiconductor device 200 in which a spacer dielectric material 410 is formed around each of the vertical structures 1120, in accordance with various embodiments.

The spacer dielectric material 410 is configured to electrically isolate the corresponding vertical structures 1120. In some embodiments, the spacer dielectric material 410 may be formed by performing at least some of the following processes: filling the second vertical openings 1110 with the spacer dielectric material 410 and partially removing the spacer dielectric material 410 to form such structure of the spacer dielectric material 410 so as to wrap around the vertical structures 1120 with the spacer dielectric material 410. Thus, the resulting vertical structures 1120 within each of the semiconductor fins 412 are formed such that the vertical structures 1120 are at least partially spaced apart by second vertical spaces 1110.

For example, a patternable layer (e.g., a photoresist mask) can be formed over the workpiece, e.g., with the hardmask layer disposed above the spacer dielectric material 410, the S/D regions 710 and the semiconductor material 210 disposed therein. Further, the patternable layer can have a pattern (e.g., one or more openings) overlaying a portion of each of the vertical structures 1120 (e.g., the vertical structures 1120 and the spacer dielectric material 410 wrapping the vertical structures 1120). By performing at least one etching process with the patternable layer as a mask, one or more openings can be formed, which can expose a portion of a sidewall of the spacer dielectric material 410 wrapping each of the vertical structures 1120, thus forming the vertical structures 1120. Following the deposition of the spacer dielectric material 410, an etching process may be performed to remove excessive spacer dielectric material 410.

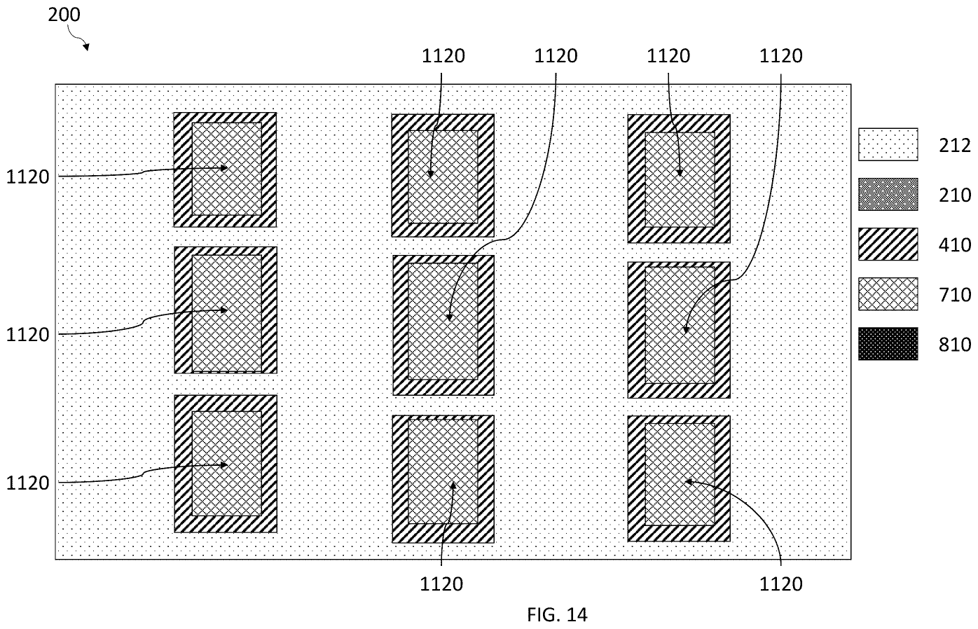

Corresponding to operation 118 of FIG. 1, FIG. 14 is a top view of the semiconductor device 200 in which the second vertical spaces 1110 (FIGS. 11 and 13) are filled with the base dielectric material 212, in accordance with various embodiments.

The base dielectric material 212 is configured to electrically isolate the corresponding vertical structures 1120. In some embodiments, the base dielectric material 212 may be formed by performing at least filling the second vertical openings 1110 with the base dielectric material 212. Following the deposition of the base dielectric material 212, an etching process described herein may be performed to remove excessive dielectric material. Also, the CMP may be performed to clean the top surface after etching.

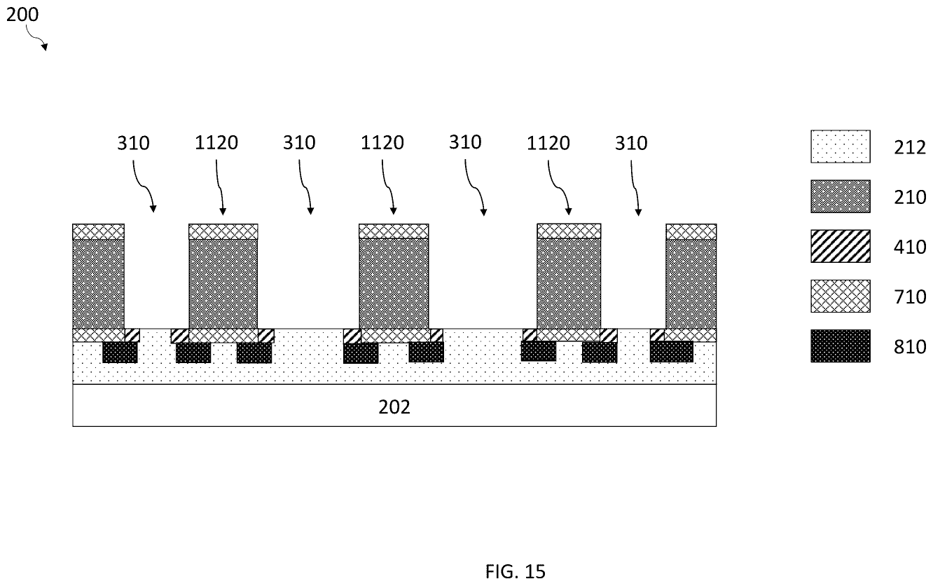

Corresponding to operation 120 of FIG. 1, FIG. 15 is a cross-sectional view of the semiconductor device 200 in which the base dielectric 212 and the spacer dielectric 410 are at least partially removed to expose the semiconductor (e.g., channel) region 720 and the topmost S/D region 710D, in accordance with various embodiments.

In some embodiments, for example, first vertical openings 310 may be formed by performing at least some of the following processes. For example, a patternable layer (e.g., a photoresist mask) can be formed over the workpiece, e.g., with the hardmask layer wherein the topmost S/D region 710D and the channel region 720 are disposed therebelow. By performing at least one etching process with the patternable layer as a mask, one or more openings in the base dielectric material 212 and the spacer dielectric 410 around the topmost S/D region 710D and the channel region 720 can be formed. These first vertical openings 310 can expose at least a portion of the channel region 720 and the topmost S/D region 710D of each of the vertical structures 1120. In some embodiments, the etching process is performed such that the portion of the spacer dielectric 410 that remains after etching as well as the junction between a base S/D region 710S and the channel region 720 are approximately on the same line with the portion of the base dielectric 212 that remained after etching.

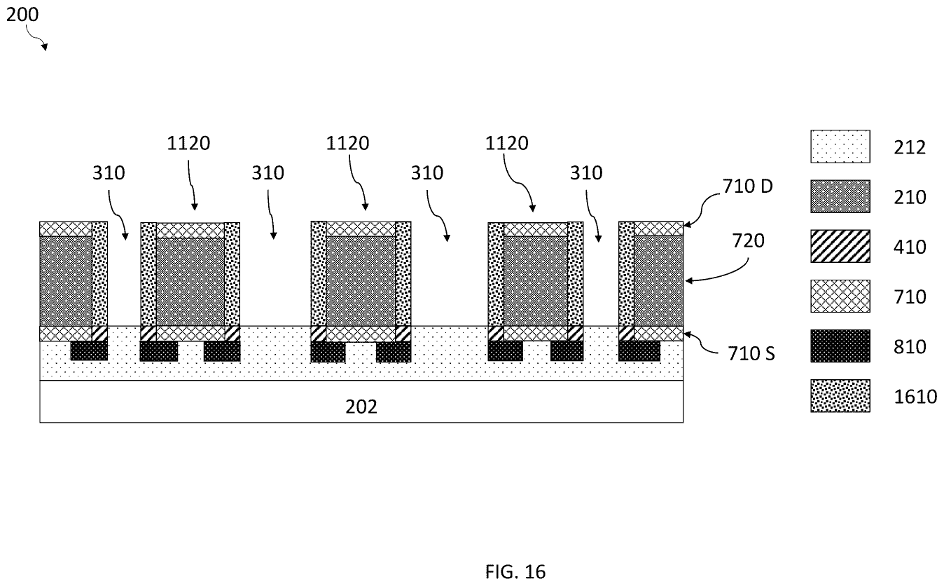

Corresponding to operation 120 of FIG. 1, FIG. 16 is a cross-sectional view of the semiconductor device 200 in which a high-k dielectric 1610 is formed around each of the wrapped channel region 720 and the topmost S/D region 710D, in accordance with various embodiments.

In FIG. 16, a semiconductor channel region 720 of the transistor is illustrated showing a first unction formed between a first S/D region 710S and a first (e.g., the base) end of the channel region 720. Also illustrated is a second junction formed between a second S/D region 710D and a second end (e.g., opposite the base end) of the channel region 720. More specifically, the second junction can be formed between the second S/D region 710D and the second end of the channel region 720.

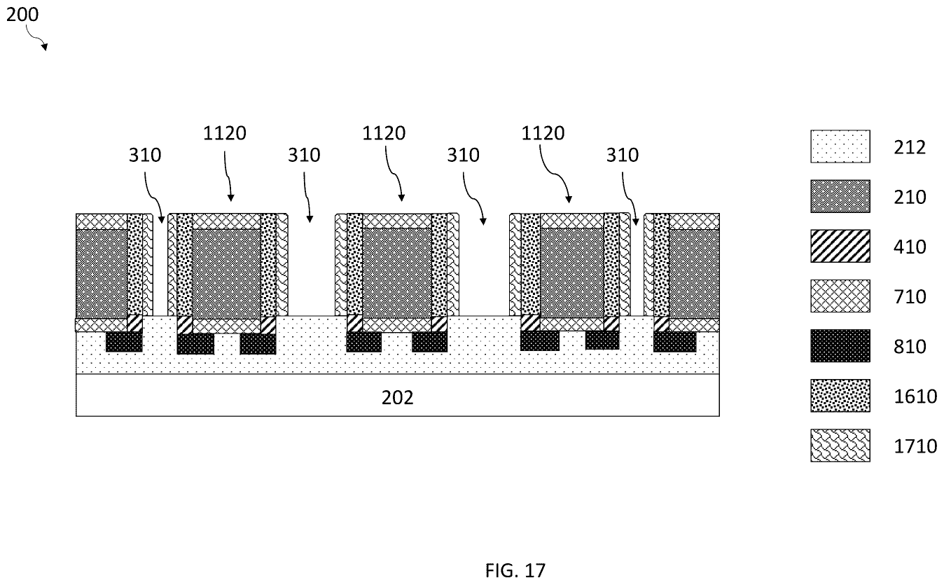

In some embodiments, various techniques may be implemented to form the high-k gate 1610 between the semiconductor (e.g., channel) region and the gate electrode 1710 (FIG. 17). One such technique utilizes a selective deposition of a high-k dielectric to form the transistor gates. In some implementations, a gate-recessing technique is utilized to allow a more uniform layer of doped conductive oxide material to form along the sidewall of the opening. Another similar technique provides a non-selective deposition of the high-k dielectric in the gate-recessed opening in conjunction with self-aligned directional etching. These techniques may also be implemented to fabricate stacked transistors of the same type by utilizing the same conductive oxide for two or more transistor layers. These and other aspects are described in further detail herein.

Further, the high-k gate 1610 may be formed by performing at least some of the following processes: filling the first vertical openings 310 with the high-k gate material 1610 and partially removing the high-k gate material 1610 to form such structure of the high-k gate 1610 so as to wrap around vertical structures 1120 that in turn comprise the channel region 720 and the upper S/D region 710D with the high-k gate material 1610.

For example, a patternable layer (e.g., a photoresist mask) can be formed over the workpiece, e.g., with the hardmask layer disposed above a portion of the high-k gate material 1610 and the vertical structures 1120 disposed therewithin. Further, the patternable layer can have a pattern (e.g., one or more openings) overlaying a portion of each of the vertical structures 1120 and portions of the high-k gate material 1610 wrapping around the channel region 720 and the upper S/D region 710D of the vertical structures 1120. By performing at least one etching process with the patternable layer as a mask, one or more openings can be formed such that each of the vertical structures 1120 is wrapped with the high-k gate material 1610. Following the deposition of the high-k gate material 1610, an etching process may be performed to remove excessive high-k gate material 1610.

The high-k dielectric 1610 can be any type of material that has a relatively large dielectric constant. As one example, a silicon oxide based gate dielectric such as silicon dioxide (SiO₂) may be selectively formed on a gate layer of silicon. Additionally or alternatively, other gate dielectric materials may be utilized such as silicon oxynitride (SiOₓN_{y}), silicon nitride (Si₃N₄), alumina (Al₂O₃), lanthanum oxide (La₂O₃), zirconium oxide (ZrO₂), hafnium oxide (HfO₂), hafnium zirconium oxide (HfZrO), tantalum oxide (Ta₂O₅), hafnium silicon oxide (HfSiO₄), zirconium silicon oxide (ZrSiO₄), titanium oxide (TiO₂), strontium titanium oxide (SrTiO₃), hafnium silicon oxynitride (HfSiOₓN_{y}), zirconium silicon oxynitride (ZrSiOₓN_{y}), hafnium oxynitride (HfOₓN_{y}), zirconium oxynitride (ZrOₓN_{y}), other suitable materials and combinations thereof. The formation methods of high-k dielectric 1610 may include molecular beam deposition (MBD), atomic layer deposition (ALD), PECVD, and the like.

Corresponding to operation 120 of FIG. 1, FIG. 17 is a cross-sectional view of the semiconductor device 200 in which gate electrodes 1710 are deposited and etched, in accordance with various embodiments.

For example, FIG. 17 illustrates a cross-sectional view of the semiconductor device 200 including the gate electrodes 1710. The gate metal 1710 may include a p-type work function layer, an n-type work function layer, multi-layers thereof, or combinations thereof, in some embodiments. Accordingly, the gate metal or gate electrode 1710 is sometimes referred to as a work function layer or work function metal. Example p-type work function metals that may be included in the gate structures for p-type devices include TiN, TaN, Ru, Mo, Al, WN, ZrSi₂, MoSi₂, TaSi₂, NiSi₂, WN, other suitable p-type work function materials, or combinations thereof. Example n-type work function metals that may be included in the gate structures for n-type devices include Ti, Ag, TaAl, TaAlC, TiAlN, TaC, TaCN, TaSiN, Mn, Zr, other suitable n-type work function materials, or combinations thereof.

The work function layer(s) or gate electrodes 1710 may be deposited by CVD, physical vapor deposition (PVD), ALD, and/or other suitable process. In various implementations, the opening formed via the etching technique can be used to deposit one or more metal structures or materials, for example the gate electrodes 1710, such as to route at least one of the gate electrodes 1710 for (e.g., electrical) connection above the transistor devices. The metal routing can be formed with one or more metal structures deposited using at least one suitable deposition technique, such that each channel region 720 and the upper S/D region 710D of the vertical structures 1120 is wrapped around with the gate electrode metal 1710. In various embodiments, upon forming the high-k dielectric 1610 and gate metal 1710 structure, a gate-all-around (GAA) FET transistor can be formed.

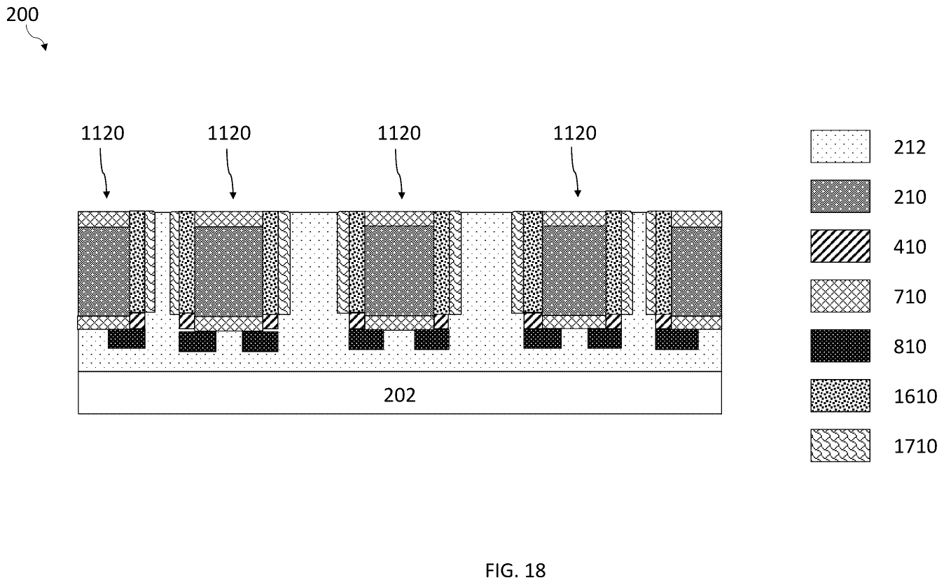

Corresponding to operation 122 of FIG. 1, FIG. 18 is a cross-sectional view of the semiconductor device 200 in which first vertical spaces or first vertical openings 310 are filled with the base dielectric material 212, in accordance with various embodiments.

The base dielectric material 212 is configured to electrically isolate the corresponding vertical structures 1120. In some embodiments, the base dielectric material 212 may be formed by performing at least filling the first vertical openings 310 with the base dielectric material 212. Following the deposition of the base dielectric material 212, an etching process may be performed to remove excessive dielectric material. Also, to complete the formation of the semiconductor device 200 after etching, the CMP can be performed to clean the top surface.

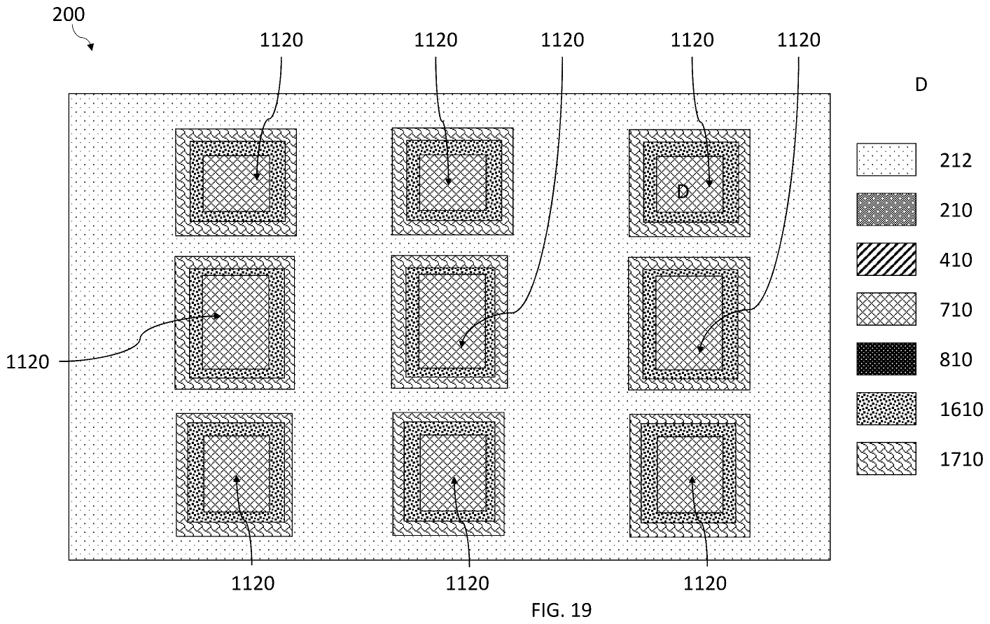

To illustrate the completed structure of the semiconductor device 200, a top view of the semiconductor device 200 is shown in FIG. 19, wherein the source metal 810 (not shown) is disposed at the base of the transistors.

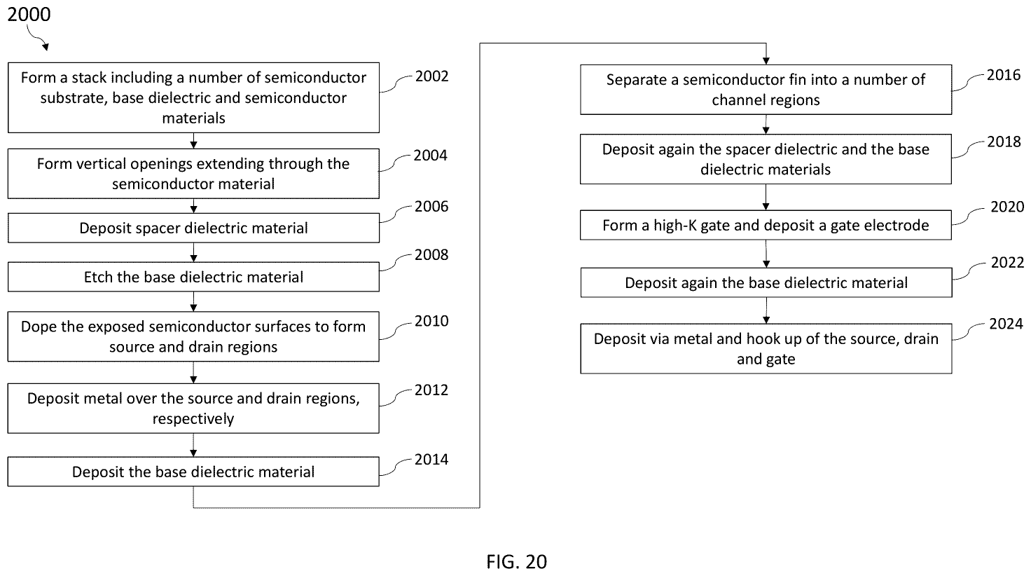

Reference is now made to FIG. 20 that illustrates a flowchart of an example method 2000 for forming a 3D high density transport device, for example, an NMOS device integrated with metal source rail wherein, for example, a non-selective metal deposition can be used. Although the semiconductor devices 200 fabricated using the NMOS device is described according to the method 2000, it should be understood that that any type of the MOSFET device, such as, for example, a PMOS, can be used to form the 3D high density transport device integrated with a metal source rail. It is noted that the method 2000 is merely an example, and is not intended to limit the present disclosure. Accordingly, it is understood that additional operations may be provided before, during, and after the method 2000 of FIG. 20, and that some other operations may only be briefly described herein.

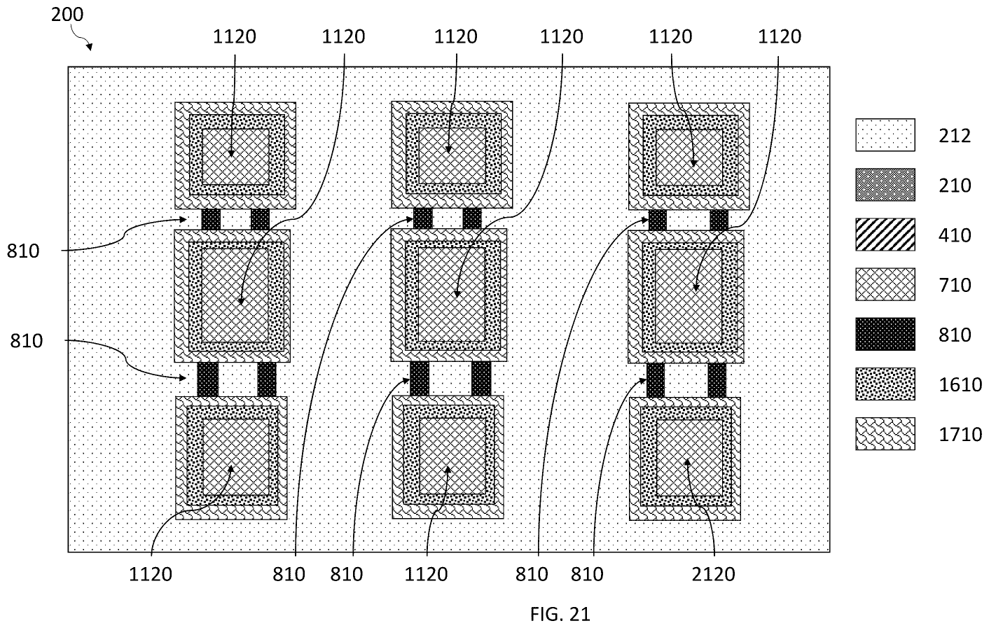

In various embodiments, some of the operations described above with respect to the method 100 (e.g., operations 102 to 122) may be reused in the method 2000, and thus, the following discussions will be focused on the different operations. Such (different) operations of the method 2000 may be associated with cross-sectional or top views of an example semiconductor device 200 at various fabrication stages as shown in FIGS. 21 to 23, respectively, which will be discussed in further detail below. Further, some of the reference numerals used for the structures in the corresponding operations 102 through 122 (e.g., operations 2002 through 2022, etc.) may be reused in FIGS. 21 to 23. It should be understood that the semiconductor device 200, shown in FIGS. 21 to 23, may include a number of other devices such as inductors, fuses, capacitors, coils, etc., while remaining within the scope of the present disclosure.

In brief overview, the method 2000 starts with operation 2002 of forming a stack of base dielectric and semiconductor materials over a substrate. The method 2000 continues to operation 2004 of patterning the semiconductor material and forming a number of vertical openings extending through the semiconductor material. The method 2000 proceeds to operation 2006 of depositing a dielectric spacer material in the vertical openings to surround the remaining semiconductor material. In some embodiments, the remaining semiconductor material may be configured as a number of semiconductor features (e.g., formed in a fin-like structure) protruding from the base dielectric material. The method 2000 proceeds to operation 2008 of forming a space underneath each of the semiconductor features by etching the base dielectric material. The method 2000 proceeds to operation 2010 of forming a source region and a drain region at top and bottom surfaces of each of the semiconductor features, respectively by, for example, plasma doping. The method 2000 proceeds to operation 2012 of deposing a metal material over the source and drain regions, respectively. The method 2000 proceeds to operation 2014 of depositing the base dielectric material. The method 2000 proceeds to operation 2016 of separating the semiconductor feature into a number of channel regions. The method 2000 proceeds to operation 2018 of depositing again the spacer dielectric material to surround each of the channel regions and then depositing the base dielectric material to surround the spacer dielectric material. The method 2000 proceeds to operation 2020 of patterning the spacer and base dielectric materials. The method 2000 continues to operations 2020 of forming a gate structure around each of the channel regions. The method 2000 continues to operations 2022 of depositing the base dielectric material to fill the vertical spaces. The method 2000 continues to operation 2024 of depositing via metal to, e.g., interconnect respective S/D regions and gates of the vertical structures 1120 with one another and externally.

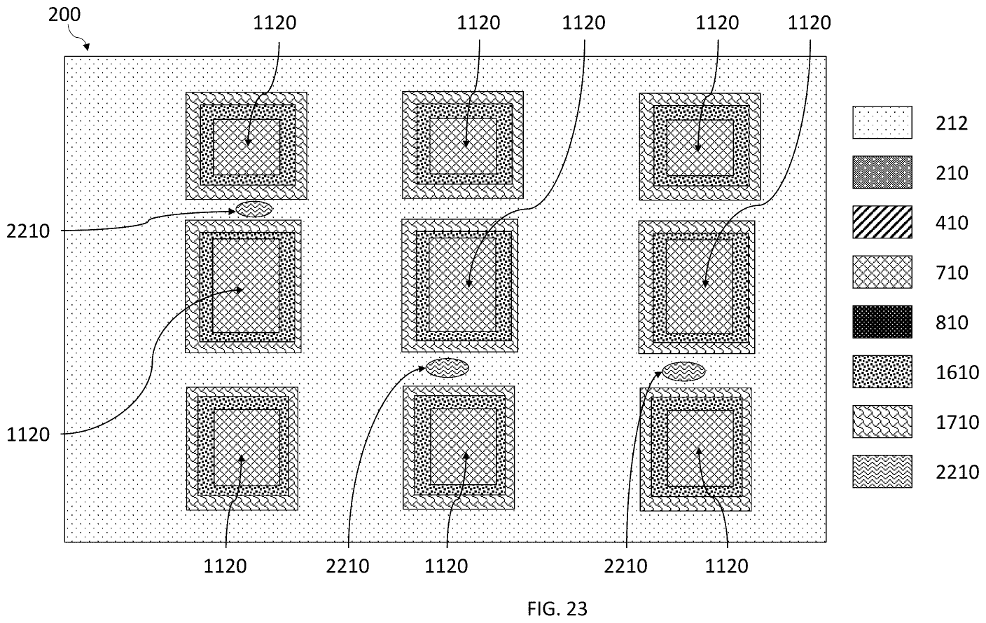

In various embodiments, most of the operations of the method 2000 are substantially similar to the operations of the method 100, except for the operation 2024 of depositing the additional base dielectric material as well as depositing the interconnect structures (e.g., vias) to hook up of the source, drain and gate of the transistors with one other and externally. With the via metal, the source/drain regions and gate of the individual structures 1120 can be connected individually and/or collectively, e.g., to the common source layout as shown in FIG. 23. The following cross-sectional views of the semiconductor device 200 will be focused on the difference with respect to the semiconductor device 200 formed according to the method 100.

Corresponding to operations 2002-2024 of FIG. 20, FIGS. 2-19 and 21-23 are cross-sectional or top views of the semiconductor device 200 in which, one or more transistors are formed, in accordance with various embodiments.

Corresponding to operation 2002 of FIG. 20, FIG. 2 is a cross-sectional view of the semiconductor device 200 in which, over a substrate 202, a stack including a semiconductor material 210 and a base dielectric material 212 is formed, in accordance with various embodiments. The operation 2002 is substantially similar to the operation 102 of the method 100, and thus, the description is not repeated.

Corresponding to operation 2004 of FIG. 20, FIG. 3 is a cross-sectional view of the semiconductor device 200 in which a number of first vertical openings 310 are formed to extend through the semiconductor material 210, in accordance with various embodiments. The operation 2004 is substantially similar to the operation 104 of the method 100, and thus, the description is not repeated.

Corresponding to operation 2006 of FIG. 20, FIGS. 4 and 5 are, respectively, cross-sectional and top views of the semiconductor device 200 in which a spacer dielectric material 410 is formed around each of the semiconductor features (e.g., formed in a fin-like structure) 412, in accordance with various embodiments. The operation 2006 is substantially similar to the operation 106 of the method 100, and thus, the description is not repeated.

Corresponding to operation 2008 of FIG. 20, FIG. 6 is a cross-sectional view of the semiconductor device 200 in which the base dielectric material 212 is patterned to form cavities 610, thereby exposing a base portion of each of the semiconductor fins 412, in accordance with various embodiments. The operation 2008 is substantially similar to the operation 108 of the method 100, and thus, the description is not repeated.

Corresponding to operation 2010 of FIG. 20, FIG. 7 is a cross-sectional view of the semiconductor device 200 in which a number of self-aligned source/drain regions 710 are formed, in accordance with various embodiments. The operation 2010 is substantially similar to the operation 110 of the method 100, and thus, the description is not repeated.

Corresponding to operation 2012 of FIG. 20, FIG. 8 is a cross-sectional view of the semiconductor device 200 in which metal deposition is selectively formed at the top and base of the transistor, in accordance with various embodiments. The operation 2012 is substantially similar to the operation 112 of the method 100, and thus, the description is not repeated.

Corresponding to operation 2014 of FIG. 20, FIG. 9 is a cross-sectional view of the semiconductor device 200 in which the first vertical spaces 310 are filled with the base dielectric material 212. The operation 2014 is substantially similar to the operation 114 of the method 100, and thus, the description is not repeated.

Corresponding to operation 2016 of FIG. 20, FIG. 9 is a cross-sectional view of the semiconductor device 200 in which etching the topmost S/D region 710, spacer dielectric material 410 and the base dielectric material 212 is performed according to the etching techniques described herein. Also, corresponding to operation 2016 of FIG. 20, FIG. 10 is a top view of the semiconductor device 200 in which the CMP is performed to clean the top surface after etching. Corresponding to operation 2016 of FIG. 20, FIG. 11 is a top view of the semiconductor device 200 in which patterning of the lateral semiconductor fins 412 is performed and a number of second vertical openings 1110 are formed to extend through the lateral semiconductor fins 412, in accordance with various embodiments. FIG. 12 illustrates the top view of the semiconductor device 200 showing the portions or vertical structures 1120 of the semiconductor fins 412 disposed on their respective source metal or rails 810, wherein the spacer dielectric 410 is removed from the top view for clarity. The operation 2016 is substantially similar to the operation 116 of the method 100, and thus, the description is not repeated.

Corresponding to operation 2018 of FIG. 20, FIG. 13 is a cross-sectional view of the semiconductor device 200 in which a spacer dielectric material 410 is formed around each of the vertical structures 1120, in accordance with various embodiments. Corresponding to operation 2018 of FIG. 20, FIG. 14 is a top view of the semiconductor device 200 in which the second vertical spaces 1110 are filled with the base dielectric material 212, in accordance with various embodiments. The operation 2018 is substantially similar to the operation 118 of the method 100, and thus, the description is not repeated.

Corresponding to operation 2020 of FIG. 20, FIG. 15 is a cross-sectional view of the semiconductor device 200 in which the base dielectric 212 and the spacer dielectric 410 are at least partially removed to expose the semiconductor (e.g., channel) region 720 and the topmost S/D region 710D, in accordance with various embodiments. Corresponding to operation 2020 of FIG. 20, FIG. 16 is a cross-sectional view of the semiconductor device 200 in which a high-k dielectric 1610 is formed around each of the wrapped channel region 720 and the topmost S/D region 710D, in accordance with various embodiments. Corresponding to operation 2020 of FIG. 20, FIG. 17 is a cross-sectional view of the semiconductor device 200 in which gate electrodes 1710 are deposited and etched, in accordance with various embodiments. The operation 2020 is substantially similar to the operation 120 of the method 100, and thus, the description is not repeated.

Corresponding to operation 2022 of FIG. 20, FIG. 18 is a cross-sectional view of the semiconductor device 200 in which first vertical spaces 310 are filled with the base dielectric material 212, in accordance with various embodiments. To illustrate the completed structure of the semiconductor device 200, a top view of the semiconductor device 200 is shown in FIG. 19, wherein the source metal 810 (not shown) is disposed at the base of the transistors. The operation 2022 is substantially similar to the operation 122 of the method 100, and thus, the description is not repeated.

FIG. 21 illustrates the top view of the semiconductor device 200 showing the portions or vertical structures 1120 disposed on their respective source metal or rails 810, wherein the base dielectric 212 is partially removed from the top view for clarity. In FIG. 21, the source metal 810 that is disposed at the base of each of the vertical structures 1120 is partially shown because the base dielectric 212 is partially removed from the top view for clarity. The source metal rail 810 is illustrated as partially disposed beneath the base S/D region 710. Though the source metal rail 810 is illustrated as a common source for several transistors, it can be formed as an individual source, e.g., only for one transistor.

Corresponding to operation 2024 of FIG. 20, FIGS. 22 and 23 are, respectively, cross-sectional and top views of the semiconductor device 200 in which metal deposition is non-selectively formed at the top of the transistor, in accordance with various embodiments.

In some embodiments, referring to FIGS. 22 and 23, the stack or wafer each include a number of interconnect structures (alternatively referred to as conductive features) formed over the device features. The interconnect structures are configured to electrically connect the device features to one another so as to form an integrated circuit, which can function as a logic device, a memory device, an input/output device, or the like. The interconnect structures may include horizontal interconnect structures, such as metal lines, and vertical interconnect structures, such as vias 2210. In some embodiments, the interconnect structures each include a conductive layer comprising any suitable conductive material, such as Cu, Al, W, Ru, other suitable materials, or combinations thereof. In some embodiments, the interconnect structures each include the conductive layer over a barrier layer, which may include Ti, Ta, TiN, TaN, other suitable materials, or combinations thereof.

For example, various openings for vias 2210 can be formed similarly as illustrated in FIGS. 22 and 23, such as using at least one suitable masking technique and etching technique. As shown, an additional layer of the dielectric material 212 can be deposited over the semiconductor device. Openings can be formed extending from the surface of the dielectric material 212 above the semiconductor device to a portion of the surface of the S/D regions and gate structures.

For example, the openings can extend to the surface of the base S/D region (e.g., bottom metal material 710S, shown as the source) and the top S/D region (e.g., top metal material 710D, shown as the drain). The openings can further extend to the surface of the gate structures, e.g., the gate electrode 1710 of the respective transistor devices. Through the openings, metal materials (e.g., shown as the via metal 2210) can be deposited in the openings using at least one suitable deposition technique. Upon the deposition, the S/D regions 710 and/or gate electrodes 1710 can be (e.g., electrically) routed vertically, extending above the transistor devices.

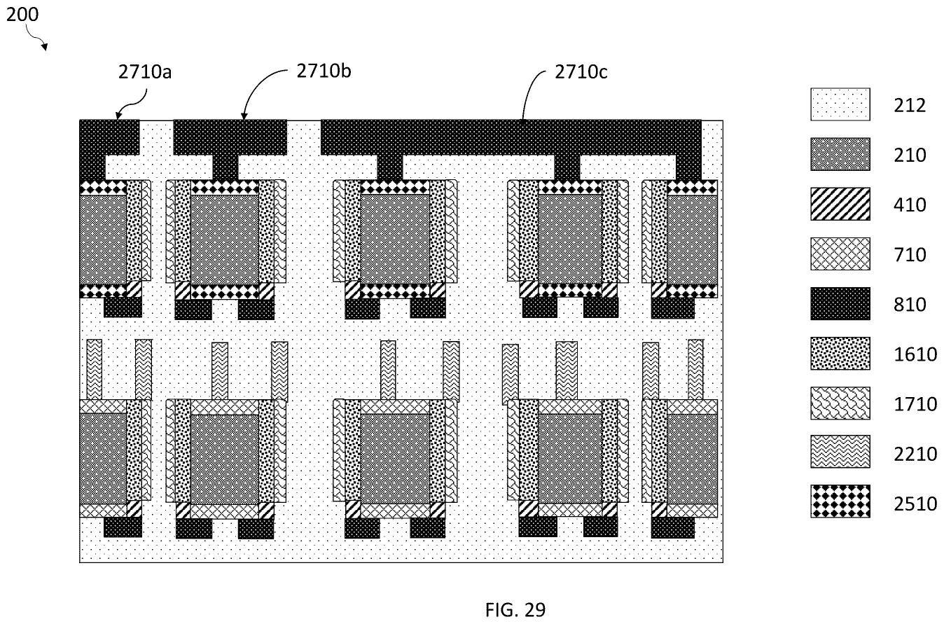

In the depicted embodiments, the interconnect structures, e.g. the vias 2210 and source metal 810 are embedded in the base dielectric layer 212. As shown in FIGS. 22 and 23, the base dielectric layer 212 can be around or surround the sidewall of the vias 2210. The base dielectric layer 212 may expose the top surface of the vias 2210. The dielectric layer 212 may extend at least along sidewalls of the vias 2210. The top surface of the vias 2210 may be substantially even or slightly recessed with respect to a plane of the top surface of the dielectric layer 212. The vias 2210 may be formed in any suitable process, such as one or more damascene processes. An additional layer of the base dielectric material 212 can be deposited above the semiconductor device. Hence, for example, a bottom wafer of the semiconductor device shown in FIG. 29 can be formed.

In various embodiments, FIG. 23 illustrates the top view of the semiconductor device 200 wherein the base dielectric layer is partially removed above the vertical structures 1120 for clarity. A layout with a common source of via electrically coupling the S/D regions 710 and the gate electrode 1710 is illustrated. In FIG. 23, several vertical structures 1120 (e.g., three consecutive vertical structures 1120 per each column in the first lateral direction) are electrically coupled to the common source. Although the semiconductor devices 200 fabricated using the common source as illustrated in FIG. 23, it should be understood that any type of the individual electrically couplings to separate sources for the S/D regions 710 and the gate electrode 1710 of the individual vertical structures 1120 may be implemented. Also, the semiconductor devices 200 using a combination of individual and common source layouts may be fabricated.

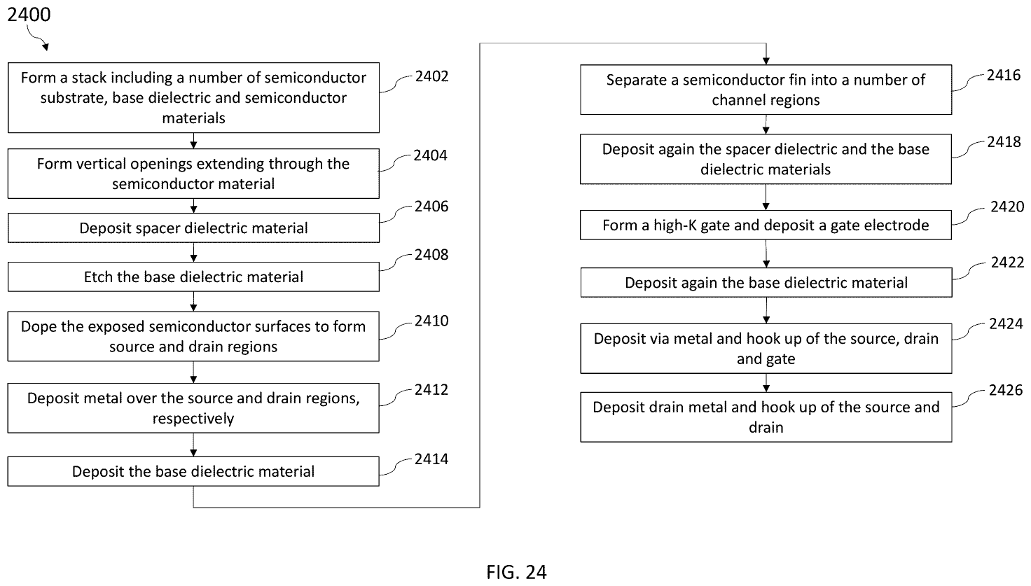

Reference is now made to FIG. 24 that illustrates a flowchart of an example method 2400 for forming a 3D high density transport device, for example, a PMOS field effect transistor wherein the source and the drain regions are formed of p-type semiconductors) device integrated with metal source rail and metal drain rail wherein, for example, a non-selective method of metal deposition can be used. Although the semiconductor devices 200 fabricated using the PMOS device is described according to the method 2400, it should be understood that that any type of the MOSFET device, such as, for example, an NMOS, can be used to form the 3D high density transport device integrated with the metal source rail and metal drain rail. It is noted that the method 2400 is merely an example, and is not intended to limit the present disclosure. Accordingly, it is understood that additional operations may be provided before, during, and after the method 2400 of FIG. 24, and that some other operations may only be briefly described herein.

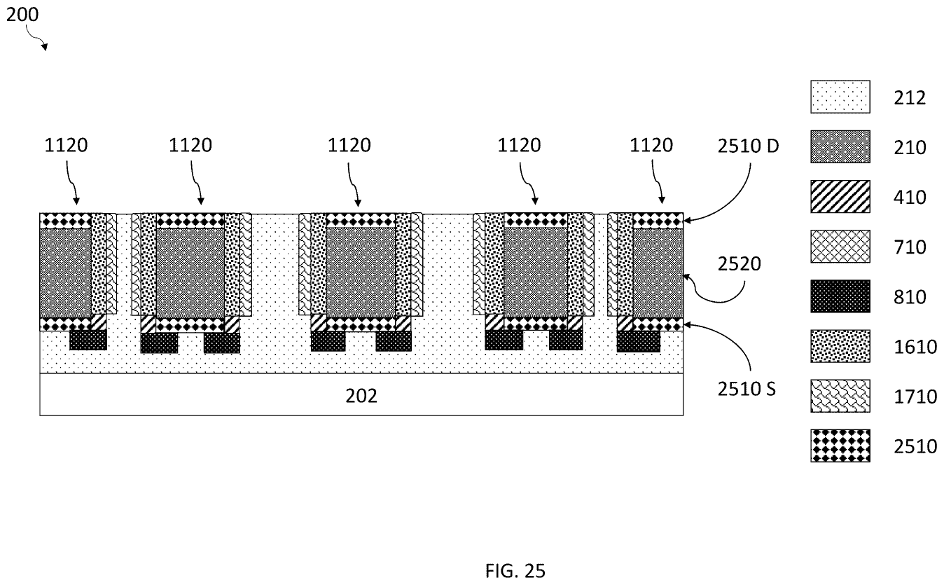

In various embodiments, some of the operations described above with respect to the method 2000 (e.g., operations 2002 to 2024) may be reused in the method 2400, and thus, the following discussions will be focused on the different operations. Such (different) operations of the method 2400 may be associated with cross-sectional or top views of an example semiconductor device 200 at various fabrication stages as shown in FIGS. 25 to 28, respectively, which will be discussed in further detail below. Further, some of the reference numerals used for the structures in the corresponding operations 2002 through 2024 (e.g., 2402 through 2424, etc.) may be reused in FIGS. 25 to 28. It should be understood that the semiconductor device 200, shown in FIGS. 25 to 28, may include a number of other devices such as inductors, fuses, capacitors, coils, etc., while remaining within the scope of the present disclosure.

In brief overview, the method 2400 starts with operation 2402 of forming a stack of base dielectric and semiconductor materials over a substrate. The method 2400 continues to operation 2404 of patterning the semiconductor material and forming a number of vertical openings extending through the semiconductor material. The method 2400 proceeds to operation 2406 of depositing a dielectric spacer material in the vertical openings to surround the remaining semiconductor material. In some embodiments, the remaining semiconductor material may be configured as a number of semiconductor features (e.g., formed in a fin-like structure) protruding from the base dielectric material. The method 2400 proceeds to operation 2408 of forming a space underneath each of the semiconductor features by etching the base dielectric material. The method 2400 proceeds to operation 2410 of forming a source region and a drain region at top and bottom surfaces of each of the semiconductor features, respectively by, for example, plasma doping. The method 2400 proceeds to operation 2412 of deposing a metal material over the source and drain regions, respectively. The method 2400 proceeds to operation 2414 of depositing the base dielectric material. The method 2400 proceeds to operation 2416 of separating the semiconductor feature into a number of channel regions. The method 2400 proceeds to operation 2418 of depositing again the spacer dielectric material to surround each of the channel regions and then depositing the base dielectric material to surround the spacer dielectric material. The method 2400 proceeds to operation 2420 of patterning the spacer and base dielectric materials. The method 2400 continues to operations 2420 of forming a gate structure around each of the channel regions. The method 2400 continues to operations 2422 of depositing the base dielectric material to fill the vertical spaces. The method 2400 continues to operation 2424 of depositing a drain rail metal to, e.g., interconnect respective S/D regions and gates of the structures 1120 with one another and externally.

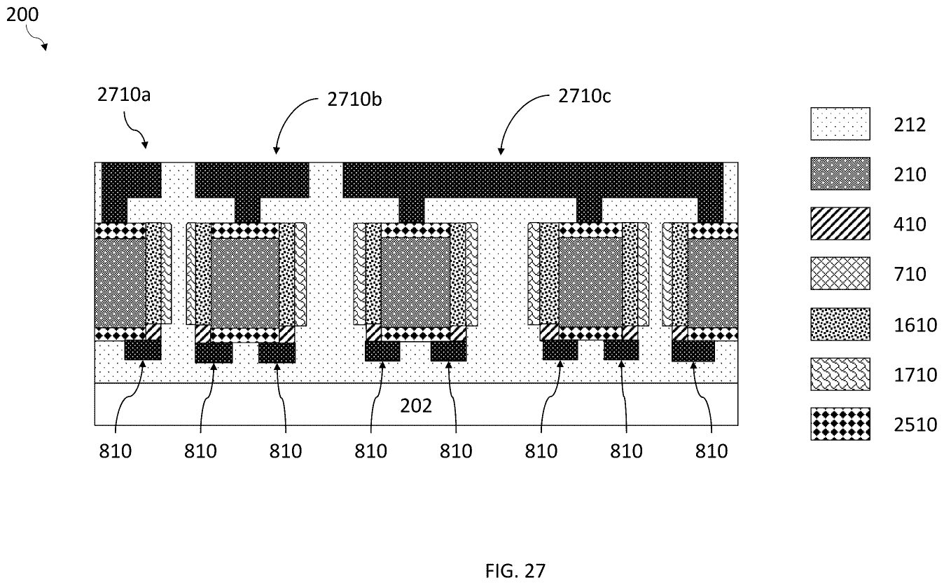

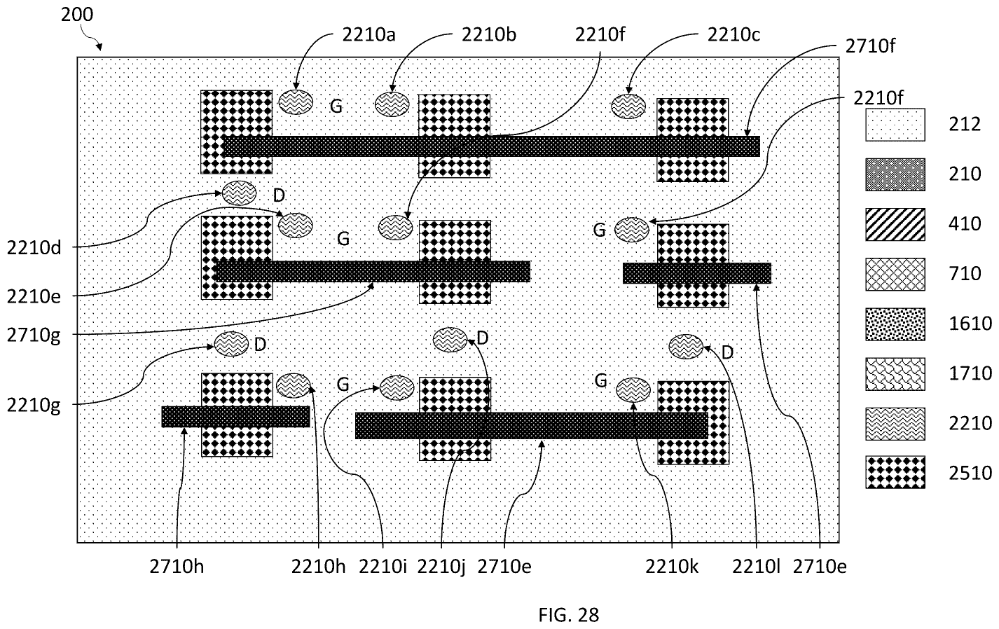

In various embodiments, most of the operations of the method 2400 are substantially similar to the operations of the method 2000, except for the following operation 2426 of depositing one or more drain rails. With the interconnect structures (e.g., vias and/or rails), source/drain regions and gate of the individual structures 1120 can be connected individually and/or collectively, e.g., to the common drain layout as shown in FIGS. 27 and 28. Accordingly, the following cross-sectional views of the semiconductor device 200 will be focused on the difference with respect to the semiconductor device 200 formed according to the method 2000.

Corresponding to operations 2402-2426 of FIG. 24, FIGS. 2-18, 21-23 and 25-28 are cross-sectional or top views of the semiconductor device 200 in which, one or more transistors are formed, in accordance with various embodiments.

Corresponding to operation 2402 of FIG. 24, FIG. 2 is a cross-sectional view of the semiconductor device 200 in which, over a substrate 202, a stack including a semiconductor material 210 and a base dielectric material 212 is formed, in accordance with various embodiments. The operation 2402 is substantially similar to the operation 2002 of the method 2000, and thus, the description is not repeated.

Corresponding to operation 2404 of FIG. 24, FIG. 3 is a cross-sectional view of the semiconductor device 200 in which a number of first vertical openings 310 are formed to extend through the semiconductor material 210, in accordance with various embodiments. The operation 2404 is substantially similar to the operation 2004 of the method 2000, and thus, the description is not repeated.

Corresponding to operation 2406 of FIG. 24, FIGS. 4 and 5 are, respectively, cross-sectional and top views of the semiconductor device 200 in which a spacer dielectric material 410 is formed around each of the semiconductor features (e.g., formed in a fin-like structure) 412, in accordance with various embodiments. The operation 2406 is substantially similar to the operation 2006 of the method 2000, and thus, the description is not repeated.

Corresponding to operation 2408 of FIG. 24, FIG. 6 is a cross-sectional view of the semiconductor device 200 in which the base dielectric material 212 is patterned to form cavities 610, thereby exposing a base portion of each of the semiconductor fins 412, in accordance with various embodiments. The operation 2408 is substantially similar to the operation 2008 of the method 2000, and thus, the description is not repeated.

| According to operation 2410 of FIG. 24, a number of self-aligned p-type source/drain regions 2510 (FIG. 25) are formed, in accordance with various embodiments. The operation 2410 is similar to the operation 110 of the method 100, except that doping, e.g. with plasma, is made using the p+ dopant, thus creating p-type S/D regions that are formed next to the semiconductor channel (which may be intrinsic or n-type). Such doping, e.g. with plasma, using the p+ dopant leads to formation of the PMOS devise unlike operation 2010 that leads to formation of the NMOS device.

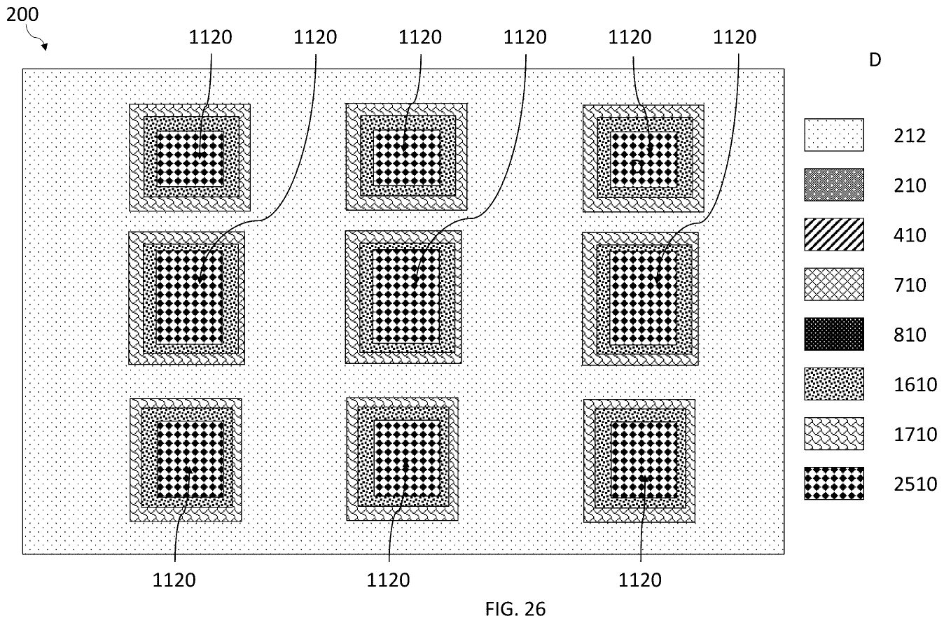

In various embodiments, the plasma doping of the both ends of the semiconductor material 210 not covered by the spacer dielectric 410 can be performed for each of the transistor structures so as to n-type dope the topmost side of the semiconductor material 210 and the bottommost base area of the semiconductor material 210 that is adjacent to the cavity or opening 610, thereby forming the p-type S/D regions 2510 (FIG. 25). In FIG. 26, a top view is illustrated in which material p-Si is formed (e.g., made up of p-type doped silicon) in the S/D regions for the vertical structures 1120, so as to form S/D regions 2510.

Therefore, operation 2410 of FIG. 24 corresponds to FIG. 7 except the above difference of the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2010 is substantially similar to operation 2010 of the method 2000, and thus, the description is not repeated.

Corresponding in most part to operation 2412 of FIG. 24, FIG. 8 is a cross-sectional view of the semiconductor device 200 in which metal deposition is selectively formed at the top and base of the transistor, in accordance with various embodiments. Operation 2412 differs from operation 2012 in the following way: the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2412 is similar to operation 2012 of method 2000, and thus, the description is not repeated.

Corresponding to operation 2414 of FIG. 24, FIG. 9 is a cross-sectional view of the semiconductor device 200 in which the first vertical spaces 310 are filled with the base dielectric material 212. Operation 2414 differs from operation 2014 in the following way: the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2414 is similar to operation 2014 of method 2000, and thus, the description is not repeated.

Corresponding to operation 2416 of FIG. 24, FIG. 9 is a cross-sectional view of the semiconductor device 200 in which etching the topmost S/D region 2510D (FIG. 25), spacer dielectric material 410 and the base dielectric material 212 is performed according to the etching techniques described herein. Also, corresponding to operation 2416 of FIG. 24, FIG. 10 is a top view of the semiconductor device 200 in which the CMP is performed to clean the top surface after etching. Corresponding to operation 2416 of FIG. 24, FIG. 11 is a top view of the semiconductor device 200 in which patterning of the lateral semiconductor fins 412 is performed and a number of second vertical openings 1110 are formed to extend through the lateral semiconductor fins 412, in accordance with various embodiments. FIG. 12 illustrates the top view of the semiconductor device 200 showing the portions or vertical structures 1120 of the semiconductor fins 412 disposed on their respective source metal or rails 810, wherein the spacer dielectric 410 is removed from the top view for clarity. Operation 2416 differs from operation 2016 in the following way: the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2416 is similar to operation 2016 of method 2000, and thus, the description is not repeated.

Corresponding to operation 2418 of FIG. 24, FIG. 13 is a cross-sectional view of the semiconductor device 200 in which a spacer dielectric material 410 is formed around each of the vertical structures 1120, in accordance with various embodiments. Corresponding to operation 2418 of FIG. 24, FIG. 14 is a top view of the semiconductor device 200 in which the second vertical spaces 1110 are filled with the base dielectric material 212, in accordance with various embodiments. Operation 2418 differs from operation 2018 in the following way: the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2418 is similar to operation 2018 of method 2000, and thus, the description is not repeated.

Corresponding to operation 2420 of FIG. 24, FIG. 15 is a cross-sectional view of the semiconductor device 200 in which the base dielectric 212 and the spacer dielectric 410 are at least partially removed to expose the semiconductor (e.g., channel) region 2520 and the topmost S/D region 2510D, in accordance with various embodiments. Corresponding to operation 2420 of FIG. 24, FIG. 16 is a cross-sectional view of the semiconductor device 200 in which a high-k dielectric 1610 is formed around each of the wrapped channel region 2520 and the topmost S/D region 2510D, in accordance with various embodiments. Corresponding to operation 2420 of FIG. 24, FIG. 17 is a cross-sectional view of the semiconductor device 200 in which gate electrodes 1710 are deposited and etched, in accordance with various embodiments. Operation 2420 differs from operation 2020 in the following way: the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2420 is similar to operation 2020 of method 2000, and thus, the description is not repeated.

Corresponding to operation 2422 of FIG. 24, FIG. 18 is a cross-sectional view of the semiconductor device 200 in which first vertical spaces 310 are filled with the base dielectric material 212, in accordance with various embodiments. Operation 2422 differs from operation 2022 in the following way: the p-type S/D regions 2510 and n-type semiconductor disposed therebetween as well as other properties of the semiconductor device 200 related to such substitution of the n-type S/D regions 710 in the NMOS device with the p-type S/D regions 2510 in the PMOS device. Other than this difference, operation 2422 is similar to operation 2022 of method 2000, and thus, the description is not repeated. FIG. 26 illustrates a top view of vertical structures 1120 upon completion of operation 2422.

FIG. 21 illustrates the top view of the semiconductor device 200 showing the portions or vertical structures 1120 disposed on their respective source metal or rails 810, wherein the base dielectric 212 is partially removed from the top view for clarity. In FIG. 21, the source metal 810 that is disposed at the base of each of the vertical structures 1120 is partially shown because the base dielectric 212 is partially removed from the top view for clarity. FIG. 21 does not illustrate the p-type S/D regions 2510 and n-type semiconductor channel 2520 disposed therebetween as well as other properties of the semiconductor device 200 related to such substitution of the n-type S/D regions 710 in the NMOS device with the p-type S/D regions 2510 in the PMOS device. The source metal rail 810 is illustrated as partially disposed beneath the base S/D region 2510S. Though the source metal rail 810 is illustrated as a common source for several transistors/vertical structures 1120, it can be formed as an individual source, e.g., only for one transistor/vertical structure 1120.

Corresponding to operation 2424 of FIG. 24, FIGS. 22 and 23 are, respectively, a cross-sectional and top views of the semiconductor device 200 in which metal deposition of vias is formed at the top of the vertical structures 1120, in accordance with various embodiments. Operation 2424 differs from operation 2024 in the following ways: the p-type S/D regions 2510 and n-type semiconductor is disposed therebetween as well as other properties of the semiconductor device 200 relate to such substitution of the n-type S/D regions 710 in the NMOS device with the p-type S/D regions 2510 in the PMOS device. Other than this difference, operation 2424 is similar to operation 2024 of the method 2000, and thus, the description is not repeated.

In some embodiments, referring to FIGS. 22-23 and 27-28, the stack or wafer each include a number of interconnect structures (alternatively referred to as conductive features) formed over the device features. The interconnect structures are configured to electrically connect the device features to one another so as to form an integrated circuit, which can function as a logic device, a memory device, an input/output device, or the like. The interconnect structures may include horizontal interconnect structures, such as metal lines, for example, drain rails 2710, and vertical interconnect structures, such as vias 2210. In various embodiments, the individual gate and source vias 2210a to 22101 are illustrated in FIG. 28 to demonstrate the difference of electrical coupling illustrated in FIG. 23 wherein the vias 2210 are electrically coupled to the common source dedicated to several vertical structures 1120 disposed in the same first lateral direction.

Corresponding to operation 2426 of FIG. 24, FIG. 27 is a cross-sectional view of the semiconductor device 200 in which metal deposition of drain rails 2710 (e.g., 2710a, 2710b, 2710c) are formed to electrically couple to top S/D regions 2510D of vertical structures 1120, in accordance with various embodiments. FIG. 28 illustrates the top view of the semiconductor device 200 showing the vertical structures 1120, wherein the base dielectric 212 is removed from the top view for clarity to illustrate the electric coupling of the top S/D regions 2510D to the drain metal or drain rails 2710.

For example, various openings for drain rails 2710 can be formed similarly as illustrated in FIGS. 27 and 28, such as using at least one suitable masking technique and etching technique. As shown, an additional layer of the dielectric material 212 can be deposited over the semiconductor device. Openings can be formed extending from the surface of the dielectric material 212 above the semiconductor device to a portion of the surface of the top S/D regions 2510D.

For example, the openings can extend from the surface of the top S/D region 2510D to the top metal material 2710, shown as the drain). Through the openings, metal material 2710 (e.g., shown as metal rail) can be deposited such that it is electrically and/or physically coupled to the openings using at least one suitable deposition technique. Upon the deposition, the S/D region can be (e.g., electrically) routed vertically, extending above the transistor devices. In some embodiments, the top surface of the base dielectric layer 212 above the top S/D region 2510D is recessed to form a trench corresponding to the dimensions of the drain rail 2710, as depicted in FIG. 27. In this regard, the drain rail 2710 protrudes from the top surface of the base dielectric layer 212 by a predetermined height configured for the fabrication/formation/manufacturing process of the semiconductor device 200, such as about 1 nm to about 10 nm, among others. In various embodiments, the top surface of the drain rail 2710 (or other interconnect structures) may correspond to a thickness of the trench such that the drain rail 2710 (or other interconnect structures) may be coplanar, or substantially coplanar, with the top surface of the base dielectric layer 212 that is disposed above the top S/D region 2510D.

In the depicted embodiments, the interconnect structures, e.g. the drain rails 2710, and source metal 810 are embedded in the base dielectric layer 212. As shown in FIGS. 27 and 28, the base dielectric layer 212 can be around or surround the sidewall and/or bottom of the drain rails 2710. The base dielectric layer 212 may expose the top surface of the interconnect structures, e.g., the drain rails 2710. The base dielectric layer 212 may extend at least from the bottom of the drain rails 2710 and along sidewalls of the drain rails 2710. The top surface of the drain rails 2710 may be substantially even or slightly recessed with respect to a plane of the top surface of the base dielectric layer 212. The interconnect structures drain rails 2710 may be formed in any suitable process. Once the depositing of the interconnect structures is completed, the remainder of the exposed S/D contact areas that appeared during depositing of the rail metal 2710 can be refilled with the base dielectric 212, as illustrated in FIG. 27. Hence, for example, a top wafer of the semiconductor device shown in FIG. 29 can be formed.

In various embodiments, FIG. 28 illustrates the top view of the semiconductor device 200 wherein the base dielectric layer is partially removed above the top S/D region 2510D for clarity. Referring to FIG. 28, a layout of electrically coupling the drain rails 2710 to the top S/D regions 2510D is illustrated. Although, as illustrated in FIGS. 27-28, the semiconductor devices 200 fabricated using the drain rail 2710 orthogonal to the source rail 810 (e.g., FIG. 25), it should be understood that the drain rails 2710 and source rails 810 can be formed with any other projection angle between each other (for example, disposed in parallel or with an angle of 45 degrees as to one another). In FIG. 28, several top S/D regions 2510D (e.g., three consecutive top S/D regions 2510D) are electrically coupled to the common drain rail 2710f In another embodiment, the drain rail 2710g electrically couples two top S/D regions 2510D to each other in a second row (wherein each row or second lateral direction is orthogonal to the first lateral direction), the drain rail 2710c is electrically coupled only to one top S/D region 2510D. In yet another embodiment, the drain rail 2710e electrically couples to two top S/D regions 2510D in the second row, the drain rail 2710h is electrically coupled only to one top S/D region 2510D that is in the same first lateral direction as the other top S/D regions 2510D from different rows that are electrically coupled to the other top S/D regions 2510D from their respective rows by the drain rails 2710f and 2710g, respectively. Although the semiconductor devices 200 fabricated using the above described layout for the common and individual drains as illustrated in FIG. 28, it should be understood that any type of the individual drain, common drain or combination thereof to electrically and/or physically couple the top S/D regions 2510D may be implemented.

Reference is now made to FIG. 29 that illustrates a cross-sectional view of a semiconductor device 200 that is formed as a bonded wafer using two or more 3D high density transport devices, for example, such devices as a PMOS, an NMOS and/or other Complementary FET (CFET) devices integrated with the metal source rail and metal drain rail that can be formed by repeating at least once the methods 2000 or 2400 or any other methods for forming the 3D high density transport device. Although the semiconductor device 200 fabricated using the PMOS device is illustrated in FIG. 29 as formed according to repeating at least once the method 2400 and the NMOS device according to repeating at least once the method 2000, it should be understood that that any type of the MOSFET device, such as, for example, the NMOS formed according to repeating at least once the method 2400 and/or PMOS formed according to repeating at least once the method 2000, or any combinations thereof can be used to form the 3D high density transport device integrated with the metal source rail and metal drain rail.

According to one implementation, a process for fabricating a semiconductor device 200 is provided utilizing selective deposition and wafer bonding technique(s). By utilizing the selective deposition technique, a recessed region can be formed above the top surface of the interconnect structures for the wafers before coupling or physically connecting the two wafers. For example, each wafer can include a respective substrate 202 (e.g., a first substrate 202 of a first wafer and a second substrate 202 of a second wafer). The first and second substrates 202 can include respective interconnect structures and the base dielectric layers 212 around the sidewall and bottom of the interconnect structures. The interconnect structures may be composed of a conductive material similar to the material or rails 810 and 2710 and/or vias 2210.

A selective deposition technique can be performed to deposit oxide materials over the top surface of the base dielectric layers 212. After depositing the oxide materials, the two wafers (e.g., with one of the wafers flipped) can be aligned and bonded or coupled via the oxide materials using at least one bonding/coupling technique. By coupling the wafers, a channel can be formed extending from the top surfaces of the respective interconnect structures. Therefore, the first and second substrates 202 can be heated/annealed, thereby expanding and physically coupling the interconnect structures of the two wafers. These operations can be followed by the CMP to complete the structure. The resulting structure in FIG. 29 can therefore include a completed semiconductor device 200, such as, for example, a CFET device, with a first transistor including S/D regions 2510D/2510S and a gate structure and a second transistor including S/D regions 710D/710S and a gate structure.

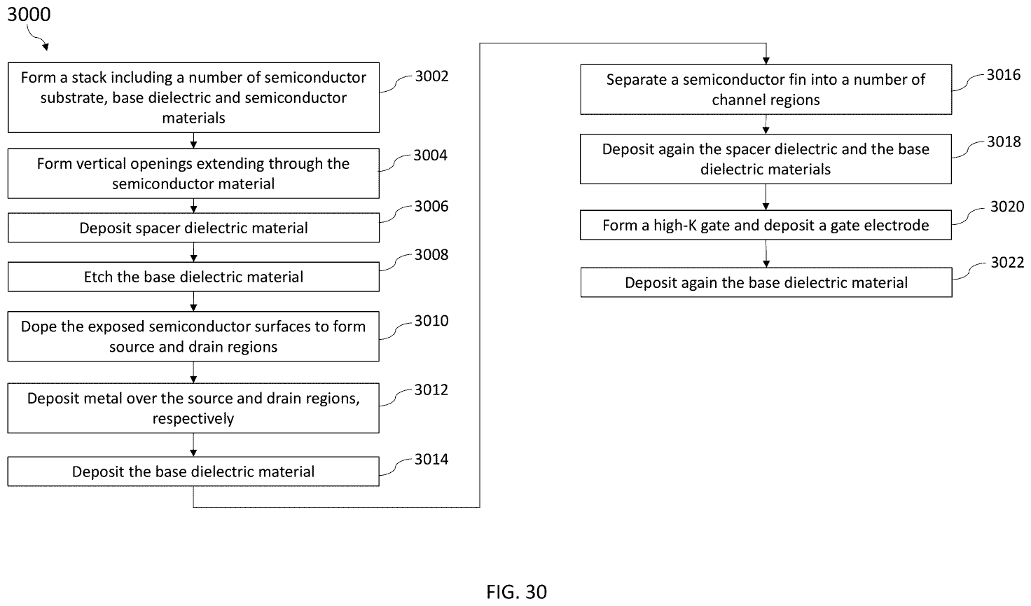

Reference is now made to FIG. 30 that illustrates a flowchart of an example method 3000 for forming a 3D high density transport device, for example, an NMOS device integrated with metal source rail wherein, for example, a cantilever support is formed for a source rail disposed at least partially or completely underneath base S/D regions. Although the semiconductor devices 200 fabricated using the NMOS device is described according to the method 3000, it should be understood that that any type of the MOSFET device, such as, for example, a PMOS, can be used to form the 3D high density transport device integrated with metal source rail. It is noted that the method 3000 is merely an example, and is not intended to limit the present disclosure. Accordingly, it is understood that additional operations may be provided before, during, and after the method 3000 of FIG. 30, and that some other operations may only be briefly described herein.

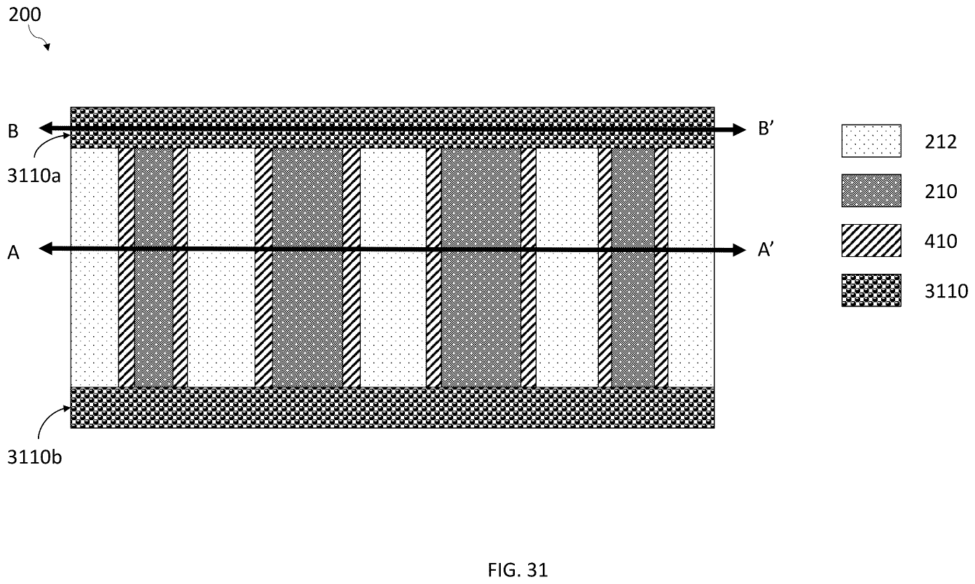

In various embodiments, some of the operations described above with respect to the method 100 (e.g., operations 102 to 122) may be reused in the method 3000, and thus, the following discussions will be focused on the different operations. Such (different) operations of the method 3000 may be associated with cross-sectional or top views of an example semiconductor device 200 at various fabrication stages as shown in FIGS. 31 to 41, respectively, which will be discussed in further detail below. Further, some of the reference numerals used for the structures in the corresponding operations 102 through 122 (e.g., 3002 through 3022, etc.) may be reused in FIGS. 31 to 41. It should be understood that the semiconductor device 200, shown in FIGS. 31 to 41, may include a number of other devices such as inductors, fuses, capacitors, coils, etc., while remaining within the scope of the present disclosure.

In brief overview, the method 3000 starts with operation 3002 of forming a stack of base dielectric and semiconductor materials over a substrate. The method 3000 continues to operation 3004 of patterning the semiconductor material and forming a number of vertical openings extending through the semiconductor material. The method 3000 proceeds to operation 3006 of depositing a dielectric spacer material in the vertical openings to surround the remaining semiconductor material. In some embodiments, the remaining semiconductor material may be configured as a number of semiconductor features (e.g., formed in a fin-like structure) protruding from the base dielectric material. The method 3000 proceeds to operation 3008 of forming a space underneath each of the semiconductor features by etching the base dielectric material. The method 3000 proceeds to operation 3010 of forming a source region and drain region at top and bottom surfaces of each of the semiconductor features, respectively by, for example, plasma doping. The method 3000 proceeds to operation 3012 of deposing a metal material over the source and drain regions, respectively. The method 3000 proceeds to operation 3014 of depositing the base dielectric material. The method 3000 proceeds to operation 3016 of separating the semiconductor feature into a number of channel regions. The method 3000 proceeds to operation 3018 of depositing again the spacer dielectric material to surround each of the channel regions and then the base dielectric material to surround the spacer dielectric material. The method 3000 proceeds to operation 3020 of patterning the spacer and base dielectric materials. The method 3000 continues to operations 3020 of forming a gate structure around each of the channel regions. The method 3000 continues to operations 3022 of depositing the base dielectric material to fill the vertical spaces.

In various embodiments, most of the operations of the method 3000 are substantially similar to the operations of the method 100, except for the operation 3008 and 3012 of etching the base dielectric material 212 and depositing the metal over the source and drain regions, respectively. These differing operations provide a cantilever support that can be formed such that a source rail may be disposed at least partially or completely underneath the base S/D regions. Accordingly, the following cross-sectional views of the semiconductor device 200 will be focused on the difference with respect to the semiconductor device 200 formed according to the method 100.

Corresponding to operations 3002-3022 of FIG. 30, FIGS. 2-5, 14-17 and 31-41 are cross-sectional or top views of the semiconductor device 200 in which, one or more transistors are formed, in accordance with various embodiments.

Corresponding to operation 3002 of FIG. 30, FIG. 2 is a cross-sectional view of the semiconductor device 200 in which, over a substrate 202, a stack including a semiconductor material 210 and a base dielectric material 212 are formed, in accordance with various embodiments. The operation 3002 is substantially similar to the operation 102 of the method 100, and thus, the description is not repeated.

Corresponding to operation 3004 of FIG. 30, FIG. 3 is a cross-sectional view of the semiconductor device 200 in which a number of first vertical openings 310 are formed to extend through the semiconductor material 210, in accordance with various embodiments. The operation 3004 is substantially similar to the operation 104 of the method 100, and thus, the description is not repeated.

Corresponding to operation 3006 of FIG. 30, FIGS. 4 and 5 are, respectively, cross-sectional and top views of the semiconductor device 200 in which a spacer dielectric material 410 is formed around each of the semiconductor feature (e.g., formed in a fin-like structure) 412, in accordance with various embodiments. The operation 3006 is substantially similar to the operation 106 of the method 100, and thus, the description is not repeated.

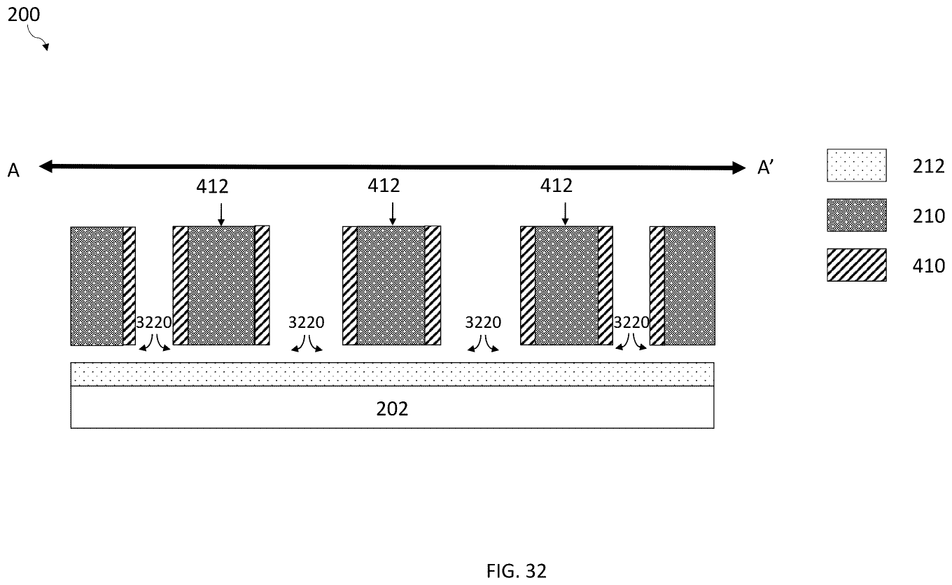

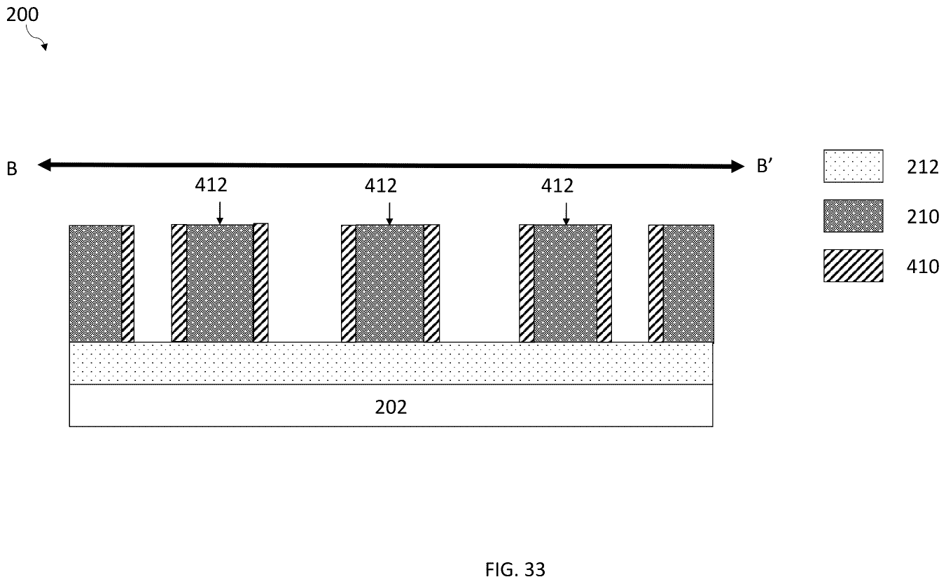

Corresponding to operation 3008 of FIG. 30, FIG. 31 is a top view of the semiconductor device 200 in which the base dielectric material 212 is patterned to form cavities or openings 3220 (FIG. 32), thereby exposing a base portion of each of the vertical structures 412, in accordance with various embodiments. To illustrate the exposed portion of each of the vertical structures 412, cross-sectional views of the semiconductor device 200 are shown in FIG. 32-33.

As illustrated, a patternable layer (e.g., a photoresist masks) can be formed over the workpiece, e.g., with the hardmask layer(s) and the base filling dielectric material 212 disposed therebelow. Optionally or alternatively, the spacer dielectric material 410 and/or the semiconductor material 210 may also be disposed below the patternable and hardmask layers. Further, the patternable layer can have a pattern illustrated in FIG. 31 as 3110a and 3110b (e.g., one or more openings) overlaying a portion of each of the vertical structures 412 and portions of the base dielectric material 212. In optional or alternative embodiments, a portion of the spacer dielectric material 410 and/or the semiconductor material 210 may also be exposed. By performing at least one etching process with the patternable layer as a mask, one or more openings below the pattern 3110a and 3110b can be formed, which can expose a portion of a sidewall of each of the vertical structures 412.

In FIGS. 31-33, along cross-section A-A′, the corresponding portion of the semiconductor material 210 (and/or the spacer dielectric material 410 that is not shown) of each of the vertical structures 412 is exposed by the opening below the pattern 3110 a, while, along cross-section B-B′, the corresponding portion of each of the vertical structures 412 may still remain covered by the base dielectric material 212. Further, one or more undercut openings 3220 underneath bases of vertical structures 412 may be formed by performing at least one etching process described herein. Thus, a cantilever feature may be formed, that is at least some middle portion of the vertical structures 412 along the lateral direction can have the openings 3220 under the entire semiconductor region 210 across the width of each of the vertical structures 412 (such width is defined orthogonally to the first lateral direction). In other embodiments, the openings 3220 can also be formed under one or both lateral ends along the first lateral direction of the vertical structures 412. Besides forming the cantilever feature, the operation 3008 is similar to the operation 108 of the method 100, and thus, the description is not repeated.

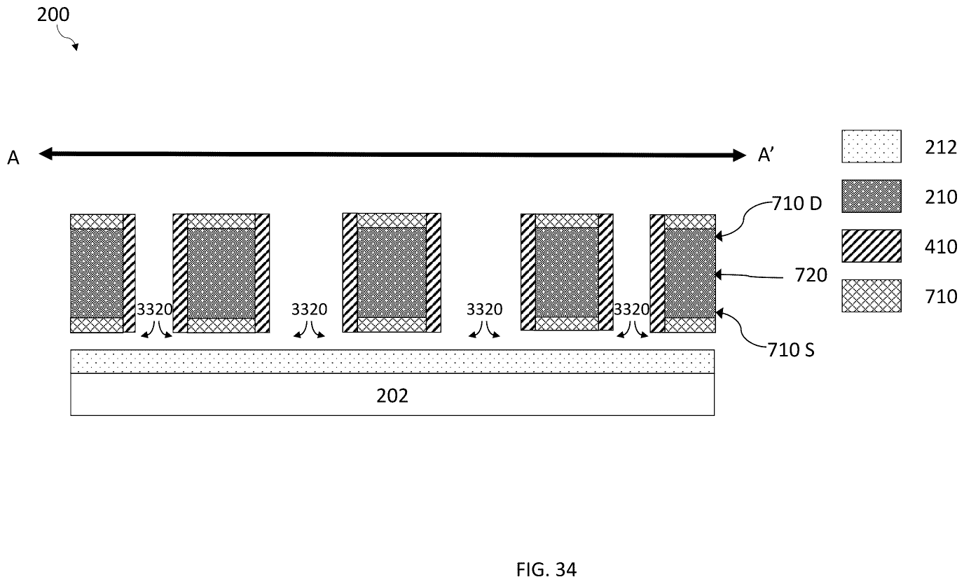

Corresponding to operation 3010 of FIG. 30, FIG. 34 is a cross-sectional view of the semiconductor device 200 in which a number of self-aligned source/drain regions 710S and 710D as well as a channel region 720 are formed, in accordance with various embodiments. Since more area underneath the semiconductor region 210 is exposed to doping (because of the cantilever feature formed according to the operation 3008), the entire exposed surface of the semiconductor region 210 at the base is doped creating a greater area of the base S/D region 710S. Besides forming a greater area of the base S/D region 710S due to the cantilever feature, operation 3010 is similar to the operation 110 of the method 100, and thus, the description is not repeated.

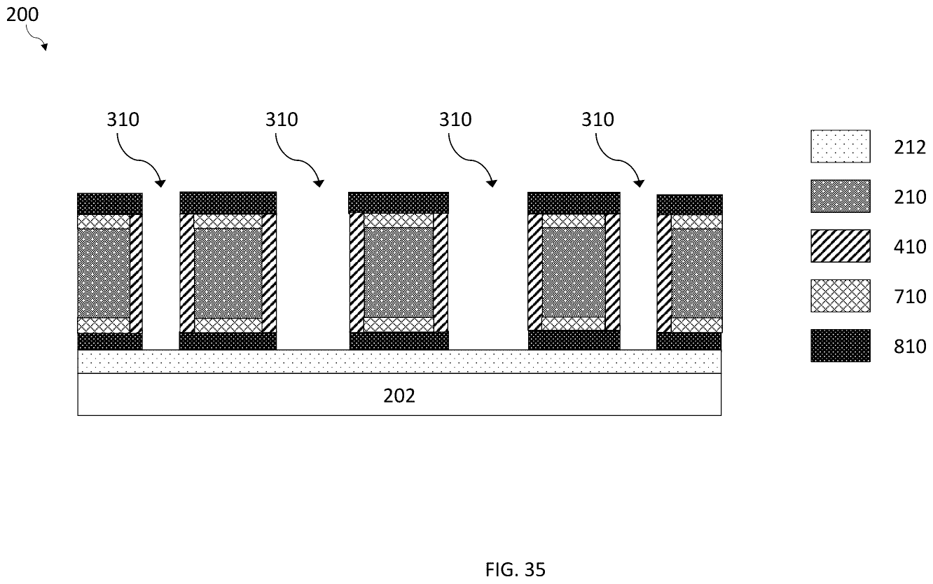

Corresponding to operation 3012 of FIG. 30, FIG. 35 is a cross-sectional view of the semiconductor device 200 in which metal deposition is selectively formed at the top and base of the transistor, in accordance with various embodiments. For example, FIG. 35 illustrates a cross-sectional view of the semiconductor device 200 including metal routings. In various implementations, the opening formed via the etching technique can be used to selectively deposit one or more metal structures or materials, for example source/drain metal (S/D metal) 810, such as to route at least one of the base and/or top S/D regions 710S, 710D for (e.g., electrical) connection above the semiconductor fins 412. The metal routing can be formed with one or more metal structures selectively deposited using at least one suitable deposition technique, for example. The selective deposition of metal and etching are performed such as to vertically align an edge of the spacer dielectric 410 with an edge of the S/D metal 810 disposed within the cavity or opening 3220 of each of the corresponding semiconductor fins 412.

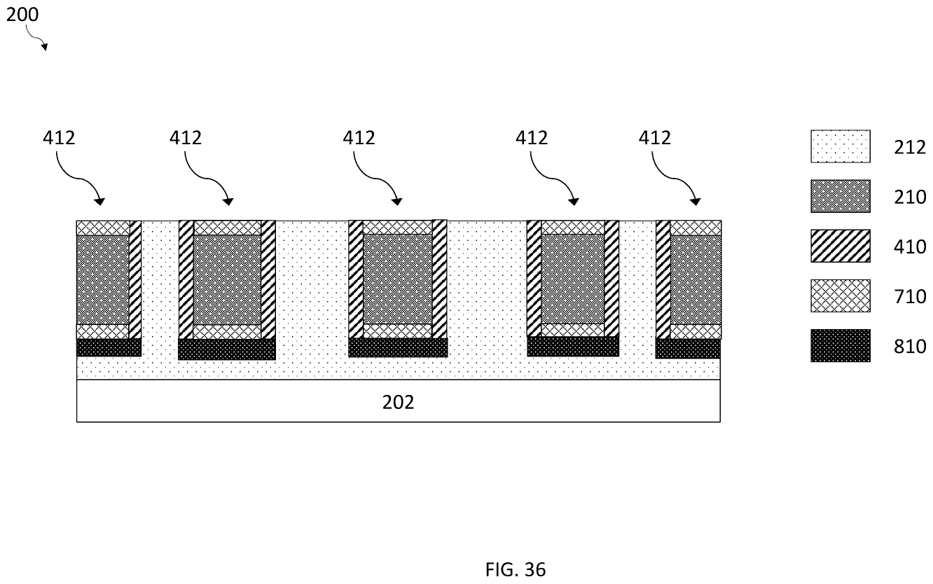

Corresponding to operation 3014 of FIG. 30, FIG. 36 is a cross-sectional view of the semiconductor device 200 in which the first vertical spaces 310 are filled with the base dielectric material 212. The operation 3014 is substantially similar to the operation 114 of the method 100, and thus, the description is not repeated.

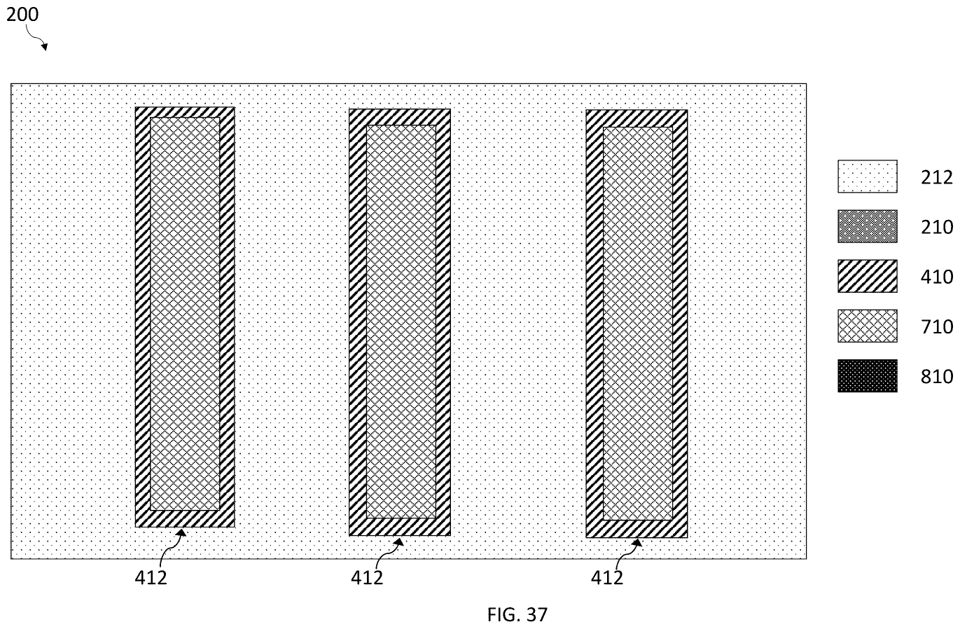

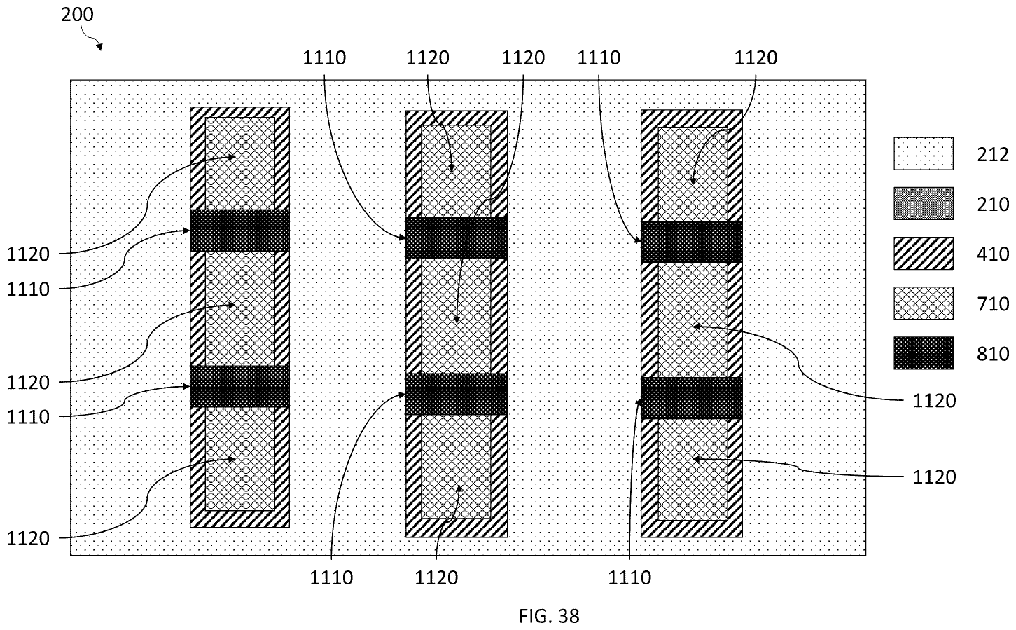

Corresponding to operation 3016 of FIG. 30, FIG. 36 is a cross-sectional view of the semiconductor device 200 in which etching the topmost S/D region 710D, spacer dielectric material 410 and the base dielectric material 212 is performed according to the etching techniques described herein. Also, corresponding to operation 3016 of FIG. 30, FIG. 37 is a top view of the semiconductor device 200 in which the CMP is performed to clean the top surface after etching. Corresponding to operation 3016 of FIG. 30, FIG. 38 is a top view of the semiconductor device 200 in which patterning of the lateral semiconductor fins 412 is performed and a number of second vertical openings 1110 are formed to extend through the lateral semiconductor fins 412, in accordance with various embodiments. The operation 3016 is substantially similar to the operation 116 of the method 100, and thus, the description is not repeated.

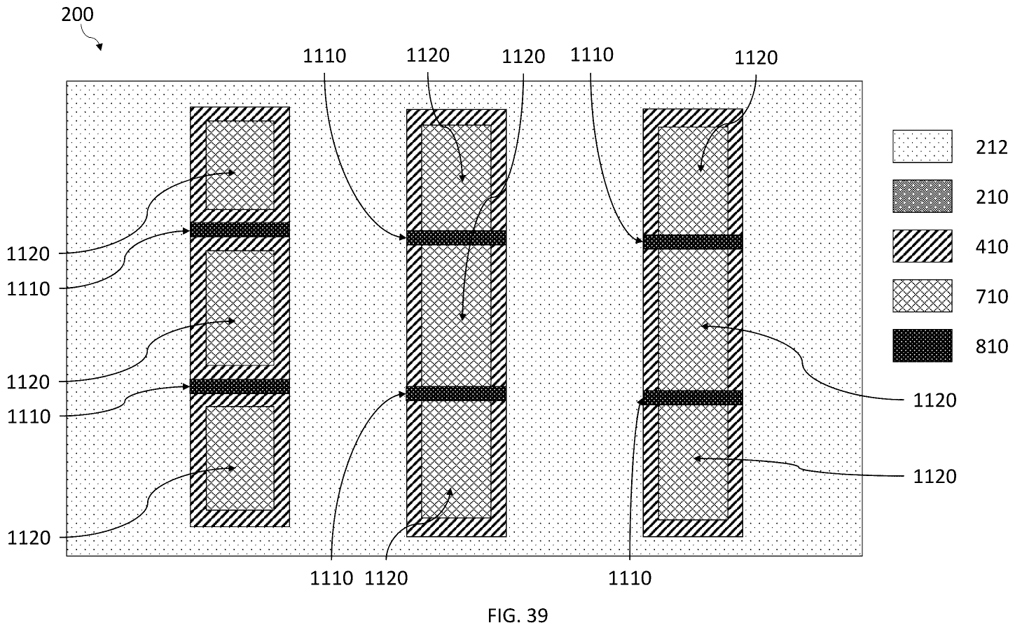

Corresponding to operation 3018 of FIG. 30, FIG. 39 is a cross-sectional view of the semiconductor device 200 in which a spacer dielectric material 410 is formed around each of the vertical structures 1120, in accordance with various embodiments. Corresponding to operation 3018 of FIG. 30, FIG. 14 is a top view of the semiconductor device 200 in which the second vertical spaces 1110 are filled with the base dielectric material 212 around the vertical structures 1120, in accordance with various embodiments. The operation 3018 is substantially similar to the operation 118 of the method 100, and thus, the description is not repeated.

Corresponding to operation 3020 of FIG. 30, FIG. 15 is a cross-sectional view of the semiconductor device 200 in which the base dielectric 212 and the spacer dielectric 410 are at least partially removed to expose the semiconductor (e.g., channel) region 720 and the topmost S/D region 710D, in accordance with various embodiments. Corresponding to operation 3020 of FIG. 30, FIG. 16 is a cross-sectional view of the semiconductor device 200 in which a high-k dielectric 1610 is formed around each of the wrapped channel region 720 and the topmost S/D region 710D, in accordance with various embodiments. Corresponding to operation 3020 of FIG. 30, FIG. 17 is a cross-sectional view of the semiconductor device 200 in which gate electrodes 1710 are deposited and etched, in accordance with various embodiments. The operation 3020 is substantially similar to the operation 120 of the method 100, and thus, the description is not repeated.

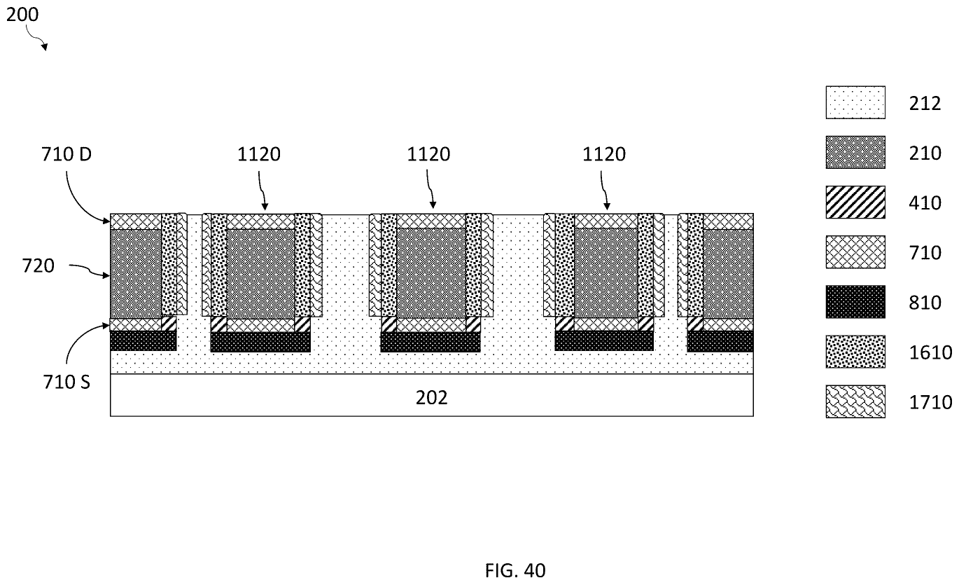

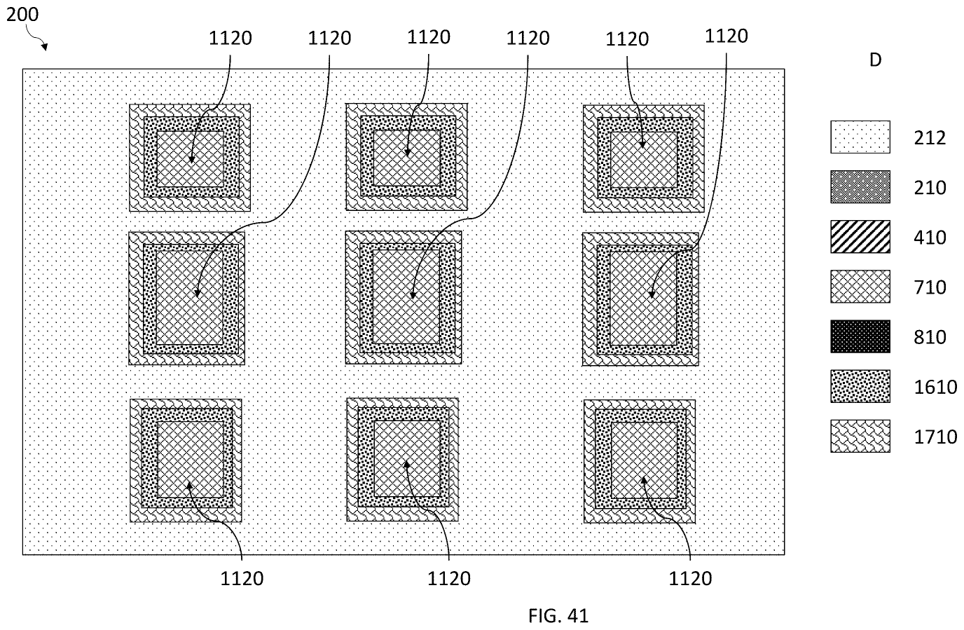

Corresponding to operation 3022 of FIG. 30, FIG. 40 is a cross-sectional view of the semiconductor device 200 in which second vertical spaces 1110 are filled with the base dielectric material 212, in accordance with various embodiments. To illustrate the completed structure of the semiconductor device 200, a top view of the semiconductor device 200 is shown in FIG. 41, wherein the source metal 810 (not shown) is disposed at the base of the transistors. The operation 3022 is substantially similar to the operation 122 of the method 100, and thus, the description is not repeated.

The optional or alternative method 3000 of forming the cantilever support described herein can be used with any other methods of forming a 3D high density transport device, such as for example, the methods 100, 2000, 2900 and/or the method of forming the semiconductor device 200 illustrated in FIG. 29.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a conductor rail disposed below one or more transistors, the conductor rail including a first portion and a second portion arranged in parallel with each other;
a lower source/drain region disposed above the conductor rail;
a channel region disposed above the lower source/drain region;
an upper source/drain region disposed above the channel region, wherein the lower source/drain region, the channel region, and the upper source/drain region each include a semiconductor material; and
a gate structure disposed around at least the channel region.

2. The semiconductor device of claim 1, wherein the lower source/drain region is in physical and electrical contact with the first and second portions of the conductor rail.

3. The semiconductor device of claim 1, further comprising a dielectric spacer disposed between the gate structure and the conductor rail, and further disposed around the lower source/drain region.

4. The semiconductor device of claim 1, further comprising:
a first via in physical and electrical contact with at least one of the first or second portion of the conductor rail;
a second via in physical and electrical contact with the gate structure; and
a third via in physical and electrical contact with the upper source/drain region.

5. The semiconductor device of claim 1, further comprising:
a second lower source/drain region also disposed above the conductor rail;
a second channel region disposed above the second lower source/drain region;
a second upper source/drain region disposed above the second channel region, wherein the second lower source/drain region, the second channel region, and the second upper source/drain region each include the semiconductor material; and
a second gate structure disposed around at least the second channel region.

6. The semiconductor device of claim 5, wherein the lower source/drain region, the channel region, the upper source/drain region, and the gate structure collectively function a first transistor of the one or more transistors, and the second lower source/drain region, the second channel region, the second upper source/drain region, and the second gate structure collectively function a second transistor.

7. The semiconductor device of claim 6, wherein the first transistor and second transistor share the conductor rail as their common source rail.

8. The semiconductor device of claim 7, further comprising a plurality of drain rails that are arranged in parallel with one another and in electrical contact with the upper source/drain region and the second upper source/drain region, respectively.

9. The semiconductor device of claim 8, wherein the common source rail extends in a first lateral direction, with the drain rails extending in a second lateral direction different from the first lateral direction.

10. The semiconductor device of claim 1, further comprising:
a second conductor rail including a first portion and a second portion, the first portion and the second portion arranged in parallel with each other, the second conductor rail disposed above the upper source/drain region;
a second lower source/drain region disposed above the second conductor rail;
a second channel region disposed above the second lower source/drain region;
a second upper source/drain region disposed above the second channel region, wherein the second lower source/drain region, the second channel region, and the second upper source/drain region each include the semiconductor material; and
a second gate structure disposed around at least the second channel region.

11. The semiconductor device of claim 10, wherein the lower and upper source/drain regions have a first conductive type, and the second lower and upper source/drain regions have a second conductive type opposite to the first conductive type.

12. A semiconductor device, comprising:
a conductor rail extending along a first lateral direction; and
a plurality of transistors disposed above the conductor rail and spaced from one another along the first lateral direction,
wherein each of the plurality of transistors includes:
a lower source/drain region disposed above the conductor rail;
a channel region disposed above the lower source/drain region;
an upper source/drain region disposed above the channel region, wherein the lower source/drain region, the channel region, and the upper source/drain region each include a semiconductor material; and
a gate structure disposed around at least the channel region.

13. The semiconductor device of claim 12, further comprising:
a second conductor rail in parallel with the conductor rail; and
a plurality of second transistors disposed above the second conductor rail and spaced from one another along the first lateral direction;
wherein each of the plurality of second transistors includes:
a second lower source/drain region disposed above the second conductor rail;
a second channel region disposed above the second lower source/drain region;
a second upper source/drain region disposed above the second channel region, wherein the second lower source/drain region, the second channel region, and the second upper source/drain region each include the semiconductor material; and
a second gate structure disposed around at least the second channel region.

14. The semiconductor device of claim 13, wherein the lower source/drain region, the upper source/drain region, the second lower source/drain region, and the second upper source/drain region all have a same conductive type.

15. The semiconductor device of claim 12, further comprising:
a second conductor rail disposed above the upper source/drain region of each of the transistors;
a second lower source/drain region disposed above the second conductor rail;
a second channel region disposed above the second lower source/drain region;
a second upper source/drain region disposed above the second channel region, wherein the second lower source/drain region, the second channel region, and the second upper source/drain region each include the semiconductor material; and
a second gate structure disposed around at least the second channel region.

16. The semiconductor device of claim 15, wherein the lower and upper source/drain regions have a first conductive type, and the second lower and upper source/drain regions have a second conductive type opposite to the first conductive type.

17. The semiconductor device of claim 12, wherein the plurality of transistors share the conductor rail as their common source rail.

18. The semiconductor device of claim 17, further comprising:
a plurality of drain rails that are arranged in parallel with one another and in electrical contact with the upper source/drain regions of the plurality of transistors, respectively;
wherein the drain rails extend in a second lateral direction different from the first lateral direction.

19. A method for fabricating semiconductor devices, comprising:
forming, over a substrate, a semiconductor feature extending along a lateral direction;
forming a conductor rail below the semiconductor feature and also extending along the lateral direction;
separating the semiconductor feature into a plurality of channel regions spaced from one another along the lateral direction; and
forming a plurality of gate structures, each of the plurality of gate structures surrounding a corresponding one of the plurality of channel regions.

20. The method of claim 19, further comprising:
prior to forming the gate structures, forming a plurality of dielectric spacers, each of the plurality of dielectric spacers surrounding a corresponding one of the plurality of channel regions; and
recessing the plurality of dielectric spacers such that each of the plurality of the recessed dielectric spacers surrounding a lower portion of the corresponding channel region that has been converted into a source/drain region.
